(19) United States
(12) Patent Application Publication
(10) Pub. No.: US 2012/0097977 A1
(43) Pub. Date: Apr. 26, 2012

(54) SEMICONDUCTOR DEVICE AND A METHOD FOR MANUFACTURING A SEMICONDUCTOR DEVICE

(75) Inventor: Tadashi YAMAGUCHI, Kanagawa (JP)

(73) Assignee: Renesas Electronics Corporation

(21) Appl. No.: 13/253,482

(22) Filed: Oct. 5, 2011

(30) Foreign Application Priority Data
Oct. 22, 2010 (JP) 2010-237309

(51) Int. Cl. H01L 29/772; H01L 21/8238

(52) U.S. Cl. 257/77; 257/192; 438/230; 438/285; 257/E29.242; 257/E21.632

(57) ABSTRACT

A semiconductor device of the present invention has a (110)-plane-orientation silicon substrate and a p channel type field effect transistor formed in a pMIS region. The p channel type field effect transistor includes a gate electrode disposed via a gate insulation film, and source/drain regions disposed inside a trench disposed in the silicon substrate on the opposite sides of the gate electrode, and including SiGe larger in lattice constant than Si. The trench has a (100)-plane-orientation first inclined surface, and a (100)-plane-orientation second inclined surface crossing the first inclined surface at a sidewall part situated on the gate electrode side. With the configuration, the angle formed between the surface (110) plane and the (100) plane of the substrate is 45°, so that the first inclined surface is formed at a relatively acute angle. This can effectively apply a compressive strain to a channel region of the p channel type MISFET.

### CROSS-REFERENCE TO RELATED APPLICATIONS

The disclosure of Japanese Patent Application No. 2010-237309 filed on Oct. 22, 2010 including the specification, drawings and abstract is incorporated herein by reference in its entirety.

### BACKGROUND

The present invention relates to a semiconductor device and a method for manufacturing a semiconductor device. More particularly, it relates to a technology effectively applicable to a semiconductor device having a MISFET.

Currently, miniaturization of a transistor, and improvement of performances thereof have been widely performed. However, the improvement of the performances of a transistor only by miniaturization has a problem of an increase in cost in view of performances.

Under such circumstances, there has been disclosed not only the improvement of performances of a transistor merely by miniaturization but also a method in which a stress is controlled to improve the performances of a transistor.

As one of the methods for improving the performances of a transistor using a stress film, there has been studied, for example, a technology of applying SiGe to source/drain regions of a p channel type MISFET formed over a Si substrate, and improving the performances. Such technologies are disclosed in, for example, Patent Documents 1 and 2 below.

Further, there has been studied a technology so-called DSL (Dual Stress Liner) as follows: a compressive stress film is formed over a p channel type MISFET, and a tensile stress film is formed over an n channel type MISFET; thus, a stress is applied to the channels of both the MISFETs to improve the performances.
[Patent Document 1]
Japanese Unexamined Patent Publication No. 2009-26795
[Patent Document 2]
Japanese Unexamined Patent Publication No. 2008-78347

### SUMMARY

The present inventors have conducted a study on the improvement of the transistor performances by applying SiGe to the source/drain regions of a p channel type MISFET (Metal Insulator Semiconductor Field Effect Transistor) formed over a Si substrate.

However, as described in details later, in manufacturing of a p channel type MISFET, when a substrate with a plane orientation of (100) is used, and a trench is formed in the source/drain forming region), the (111) plane is exposed at the side surface. Such a plane is relatively larger in angle formed with the (100) plane. As a result, even when SiGe is epitaxially grown in the insides of the trenches to form the source/drain regions, the stress applied to the channel is reduced.

Accordingly, in order to more effectively apply a stress to the channel, there has been a demand for the improvement of the device structure, and a study of a manufacturing method for implementing the device configuration.

Under such circumstances, it is an object of the present invention to provide a technology capable of improving the characteristics of a semiconductor device.

Further, it is another object of the present invention to provide a method for manufacturing a semiconductor device, capable of improving the characteristics of the semiconductor device.

The foregoing and other objects and novel features of the present invention will be apparent from the description of this specification and the accompanying drawings.

Summaries of the representative ones of the inventions disclosed in the present application will be described in brief as follows.

Of the inventions disclosed in the present application, a semiconductor device shown in a representative embodiment has (a) a substrate having a plane orientation of (110), and including a first semiconductor, and (b) a p channel type field effect transistor formed in a first region of the substrate. The p channel type field effect transistor has (b1) a gate electrode disposed over the first region via a gate insulation film, and (b2) source/drain regions disposed in the inside of a trench disposed in the substrate on the opposite sides of the gate electrode, and including a second semiconductor larger in lattice constant than the first semiconductor. The trench has a first inclined surface with a plane orientation of (100), and a second inclined surface with a plane orientation of (100) crossing the first inclined surface, at a sidewall part situated on the gate electrode side.

Of the inventions disclosed in the present application, a semiconductor device shown in a representative embodiment has (a) a substrate having a first region with a plane orientation of (110), and a second region with a plane orientation of (100), and including a first semiconductor; (b) a p channel type field effect transistor formed in the first region of the substrate; and (c) an n channel type field effect transistor formed in the second region of the substrate. The p channel type field effect transistor of (b) has (b1) a first gate electrode disposed over the first region via a first gate insulation film, and (b2) first source/drain regions disposed in the inside of a trench disposed in the substrate on the opposite sides of the first gate electrode, and including a second semiconductor larger in lattice constant than the first semiconductor. The n channel type field effect transistor of (c) has (c1) a second gate electrode disposed over the second region via a second gate insulation film, and (c2) second source/drain regions disposed in the substrate on the opposite sides of the second gate electrode, and including the first semiconductor. The trench has a first inclined surface with a plane orientation of (100), and a second inclined surface with a plane orientation of (100) crossing the first inclined surface, at a sidewall part situated on the first gate electrode side.

Of the inventions disclosed in the present application, a method for manufacturing a semiconductor device shown in a representative embodiment includes the steps of: (a) preparing a substrate having at least a first region with a plane orientation of (110), and including a first semiconductor; and (b) forming a first gate electrode over the first region of the substrate via a first gate insulation film. Further, the method includes the steps of; (c) forming a sidewall film on the opposite sides of the first gate electrode; and (d) with the sidewall film as a mask, dry etching the substrate on the opposite sides of the first gate electrode, and thereby forming a first trench in the substrate on the opposite sides of the first gate electrode. Still further, the method includes a step of (e) subjecting the first trench to anisotropic wet etching, and thereby forming a second trench having a first inclined surface with a plane orientation of (100), and a second inclined surface with a plane orientation of (100) crossing the first inclined surface at a sidewall part situated on the first gate electrode side. Furthermore, the method includes a step of (f) epitaxially growing a second semiconductor larger in lattice constant than the first semiconductor from the first inclined surface and the second inclined surface, and thereby forming a semiconductor region including the second semiconductor in the second trench.

In accordance with semiconductor devices shown in the following representative embodiments of the inventions disclosed in the present application, it is possible to improve the characteristics of the semiconductor devices.

Further, in accordance with the methods for manufacturing a semiconductor device shown in the following representative embodiments of the inventions disclosed in the present application, it is possible to manufacture a semiconductor device excellent in characteristics.

### BRIEF DESCRIPTION OF THE DRAWINGS

FIG. 1 is an essential part cross-sectional view showing a manufacturing step of a semiconductor device of a first embodiment;

FIG. 2 is an essential part cross-sectional view showing a manufacturing step of the semiconductor device of the first embodiment, which is the essential part cross-sectional view of the semiconductor device during the manufacturing step following that of FIG. 1;

FIG. 3 is an essential part cross-sectional view showing a manufacturing step of the semiconductor device of the first embodiment, which is the essential part cross-sectional view of the semiconductor device during the manufacturing step following that of FIG. 2;

FIG. 4 is an essential part cross-sectional view showing a manufacturing step of the semiconductor device of the first embodiment, which is the essential part cross-sectional view of the semiconductor device during the manufacturing step following that of FIG. 3;

FIG. 5 is an essential part cross-sectional view showing a manufacturing step of the semiconductor device of the first embodiment, which is the essential part cross-sectional view of the semiconductor device during the manufacturing step following that of FIG. 4;

FIG. 6 is an essential part cross-sectional view showing a manufacturing step of the semiconductor device of the first embodiment, which is the essential part cross-sectional view of the semiconductor device during the manufacturing step following that of FIG. 5;

FIG. 7 is a cross-sectional view for illustrating an etching step in manufacturing steps of the semiconductor device of the first embodiment;

FIG. 8 is a plan view for illustrating an etching step in manufacturing steps of the semiconductor device of the first embodiment;

FIG. 9 is a plan view for schematically showing the plane orientation of a silicon substrate 1 and the disposition direction of a gate electrode GE2;

FIG. 10 is a cross-sectional view for illustrating an etching step in manufacturing steps of the semiconductor device of the first embodiment, which is the cross-sectional view after first etching following that of FIG. 7;

FIG. 11 is a cross-sectional view for illustrating an etching step in manufacturing steps of the semiconductor device of the first embodiment, which is the cross-sectional view after second etching following that of FIG. 10;

FIG. 12 is a view showing the etching direction of the silicon substrate;

FIG. 13 is a graph showing the relationship between the TMAH treatment time (s) and the recess amount (nm) in each plane orientation of the silicon substrate;

FIG. 14 is a cross-sectional view showing an etching step in manufacturing steps of a semiconductor device of Comparative Example;

FIG. 15 is a plan view for illustrating the etching step in the manufacturing steps of the semiconductor device of Comparative Example;

FIG. 16 is a cross-sectional view showing the shape of the trench of the semiconductor device of the first embodiment, and the shape of the trench of the semiconductor device of Comparative Example;

FIG. 17 is a graph showing the mobility of holes in p channel type MISFETs in the semiconductor device of the first embodiment and the semiconductor device of Comparative Example;

FIG. 18 is an essential part cross-sectional view showing another configuration of the semiconductor device of the first embodiment;

FIG. 19 is an essential part cross-sectional view showing a manufacturing step of the semiconductor device of the first embodiment, which is the essential part cross-sectional view of the semiconductor device during the manufacturing step following that of FIG. 11;

FIG. 20 is an essential part cross-sectional view showing a manufacturing step of the semiconductor device of the first embodiment, which is the essential part cross-sectional view of the semiconductor device during the manufacturing step following that of FIG. 19;

FIG. 21 is a cross-sectional view showing the shape of a silicon germanium region of the semiconductor device of the first embodiment and the shape of a silicon germanium region of the semiconductor device of Comparative Example;

FIG. 22 is an essential part cross-sectional view showing a manufacturing step of the semiconductor device of the first embodiment, which is the essential part cross-sectional view of the semiconductor device during the manufacturing step following that of FIG. 20;

FIG. 23 is an essential part cross-sectional view showing a manufacturing step of the semiconductor device of the first embodiment, which is the essential part cross-sectional view of the semiconductor device during the manufacturing step following that of FIG. 22;

FIG. 24 is an essential part cross-sectional view showing a manufacturing step of the semiconductor device of the first embodiment, which is the essential part cross-sectional view of the semiconductor device during the manufacturing step following that of FIG. 23;

FIG. 25 is an essential part cross-sectional view showing a manufacturing step of the semiconductor device of the first embodiment, which is the essential part cross-sectional view of the semiconductor device during the manufacturing step following that of FIG. 24;

FIG. 26 is an essential part cross-sectional view showing a manufacturing step of the semiconductor device of the first embodiment, which is the essential part cross-sectional view of the semiconductor device during the manufacturing step following that of FIG. 25;

FIG. 27 is an essential part cross-sectional view showing a manufacturing step of the semiconductor device of the first embodiment, which is the essential part cross-sectional view of the semiconductor device during the manufacturing step following that of FIG. 26;

FIG. 28 is an essential part cross-sectional view showing a manufacturing step of the semiconductor device of the first embodiment, which is the essential part cross-sectional view of the semiconductor device during the manufacturing step following that of FIG. 27;

FIG. 29 is an essential part cross-sectional view showing a manufacturing step of the semiconductor device of the first embodiment, which is the essential part cross-sectional view of the semiconductor device during the manufacturing step following that of FIG. 28;

FIG. 30 is an essential part cross-sectional view showing a manufacturing step of the semiconductor device of the first embodiment, which is the essential part cross-sectional view of the semiconductor device during the manufacturing step following that of FIG. 29;

FIG. 31 is an essential part cross-sectional view showing a manufacturing step of the semiconductor device of the first embodiment, which is the essential part cross-sectional view of the semiconductor device during the manufacturing step following that of FIG. 30;

FIG. 32 is a plan view showing a configuration example of a semiconductor chip using the semiconductor device of the first embodiment;

FIG. 33 is a photograph (diagram) showing the cross section of the semiconductor device (p channel type MISFET Qp1) of the first embodiment;

FIG. 34 is a reproduced diagram of the photograph (diagram) shown in FIG. 33;

FIG. 35 is a cross-sectional view for illustrating an etching step in manufacturing steps of a semiconductor device of the second embodiment;

FIG. 36 is a cross-sectional view for illustrating the etching step in the manufacturing steps of the semiconductor device of the second embodiment, which is a cross-sectional view of the semiconductor device in the manufacturing step following that of FIG. 35;

FIG. 37 is an essential part cross-sectional view showing a manufacturing step of a semiconductor device of Applied Example 1 of the fifth embodiment;

FIG. 38 is an essential part cross-sectional view showing a manufacturing step of a semiconductor device of Applied Example 2 of the fifth embodiment;

FIG. 39 is an essential part cross-sectional view showing a manufacturing step of a semiconductor device of Applied Example 3 of the fifth embodiment;

FIG. 40 is an essential part cross-sectional view showing a manufacturing step of the semiconductor device of Applied Example 3 of the fifth embodiment, which is the essential part cross-sectional view of the semiconductor device during the manufacturing step following that of FIG. 39;

FIG. 41 is an essential part cross-sectional view showing a manufacturing step of a semiconductor device of Applied Example 4 of the fifth embodiment;

FIG. 42 is an essential part cross-sectional view showing a manufacturing step of the semiconductor device of Applied Example 4 of the fifth embodiment, which is the essential part cross-sectional view of the semiconductor device during the manufacturing step following that of FIG. 41;

FIG. 43 is an essential part cross-sectional view showing a manufacturing step of the semiconductor device of Applied Example 4 of the fifth embodiment, which is the essential part cross-sectional view of the semiconductor device during the manufacturing step following that of FIG. 42; and

FIG. 44 is an essential part cross-sectional view showing a manufacturing step of the semiconductor device of Applied Example 4 of the fifth embodiment, which is the essential part cross-sectional view of the semiconductor device during the manufacturing step following that of FIG. 43.

### DETAILED DESCRIPTION

Below, referring to the accompanying drawings, embodiments showing the present invention will be described in details.

In the following embodiment, the embodiment may be described in a plurality of divided sections or embodiments for convenience, if required. However, unless otherwise specified, these are not independent of each other, but are in a relation such that one is a modified example, an applied example, detailed explanation, complementary explanation, or the like of a part or the whole of the other. Further, in the following embodiments, when a reference is made to the number of elements, and the like (including number, numerical value, quantity, range, or the like), the number of elements is not limited to the specific number, but may be greater than or less than the specific number, unless otherwise specified, and except the case where the number is apparently limited to the specific number in principle, and other cases.

Further, in the following embodiments, the constitutional elements (including element steps, or the like) are not always essential, unless otherwise specified, and except the case where they are apparently considered essential in principle, and other cases. Similarly, in the following embodiments, when a reference is made to the shapes, positional relationships, or the like of the constitutional elements, or the like, it is understood that they include ones substantially analogous or similar to the shapes or the like, unless otherwise specified, unless otherwise considered apparently in principle, and except for other cases. This also applies to the foregoing numbers and the like (including number, numerical value, quantity, range, or the like).

Below, embodiments of the present invention will be described in details by reference to the accompanying drawings. Incidentally, in all the drawings for describing the embodiments, the members having the same function are given the same or related reference signs and numerals, and a repeated description thereon is omitted. Further, in the following embodiments, a description on the same or similar parts will not be repeated in principle, unless particularly required.

Further, in drawings to be used in embodiments, hatching may be omitted for ease of understanding of the drawings even in a cross-sectional view. Whereas, for ease of understanding of the drawings, hatching may be provided even in a plan view

### First Embodiment

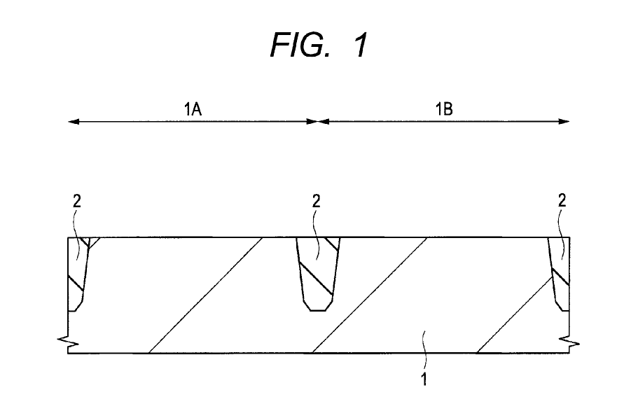

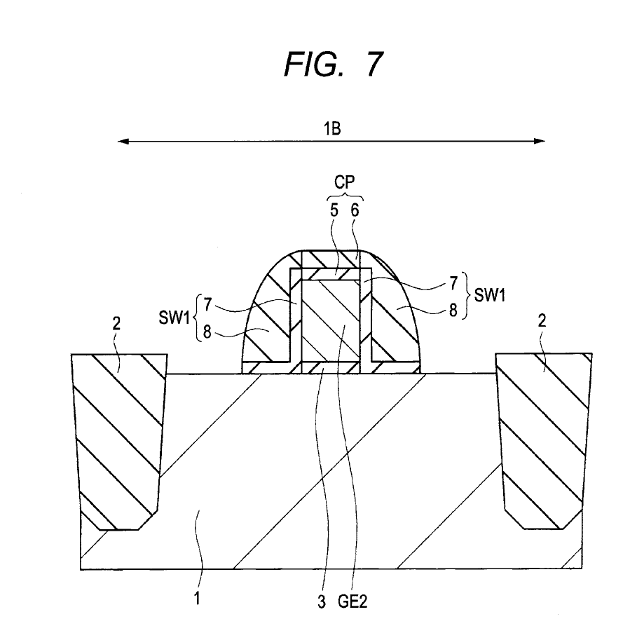

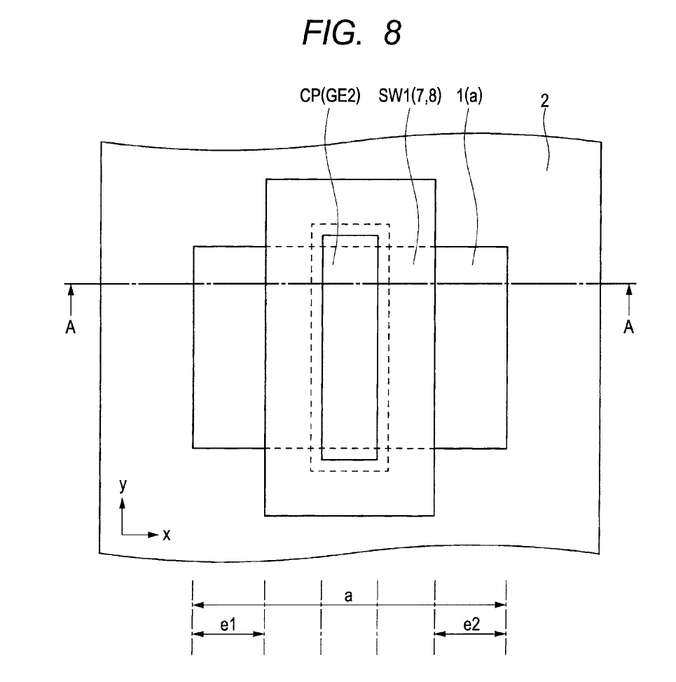

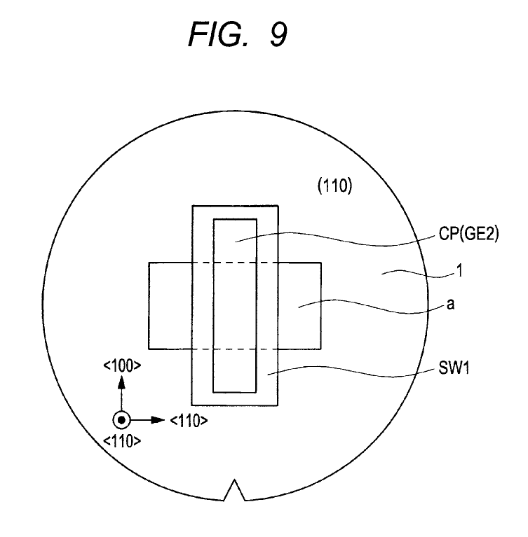

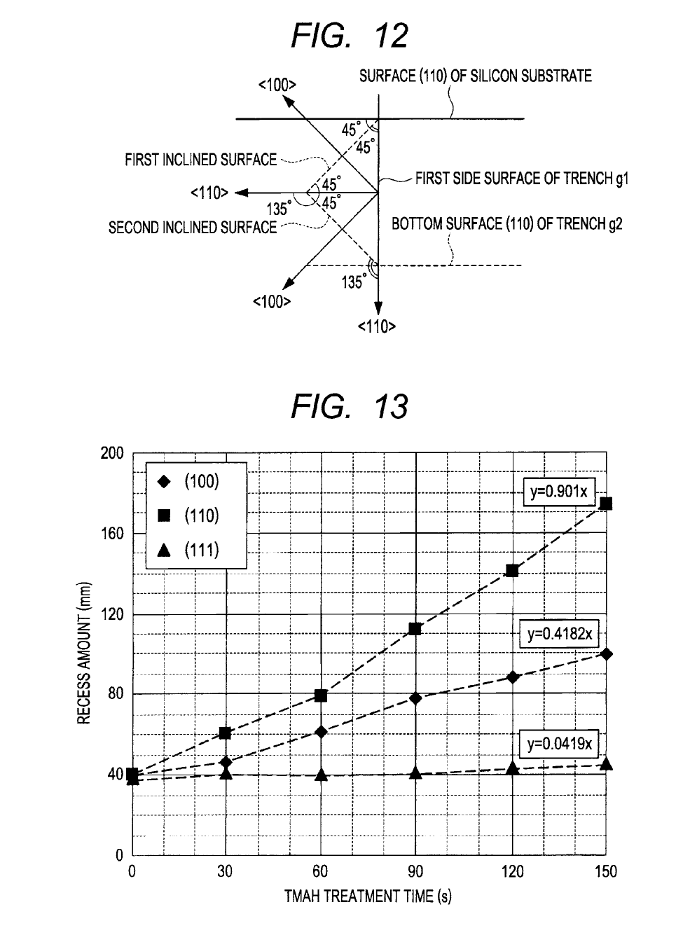

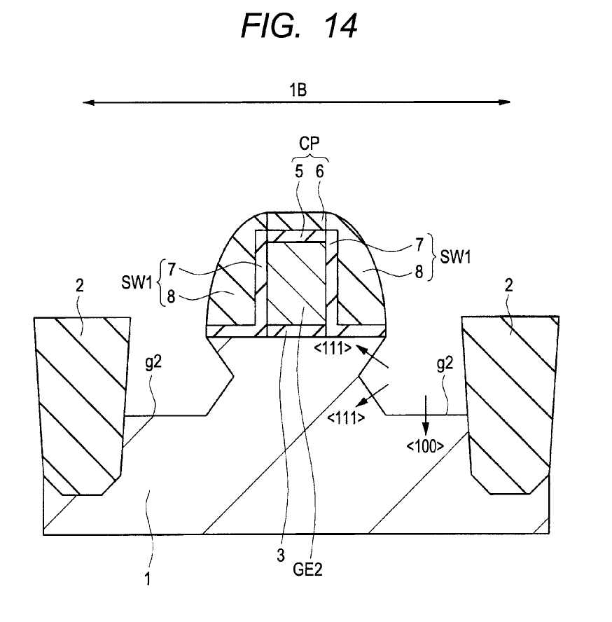

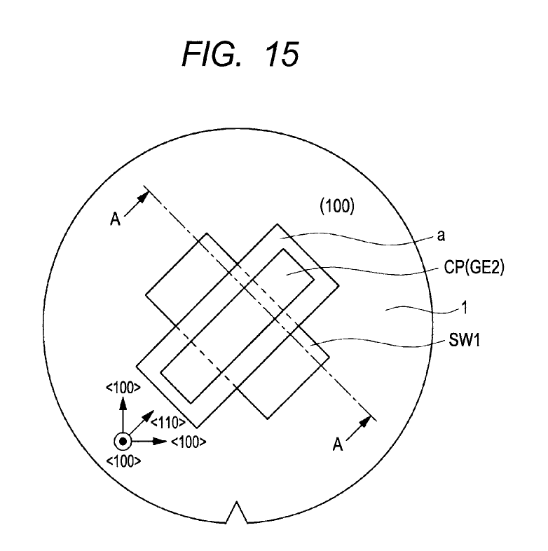

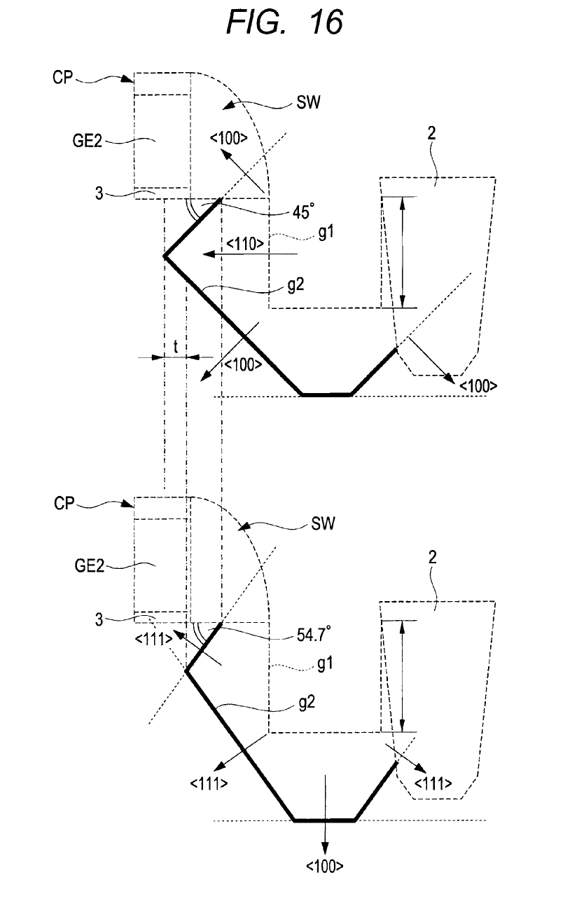

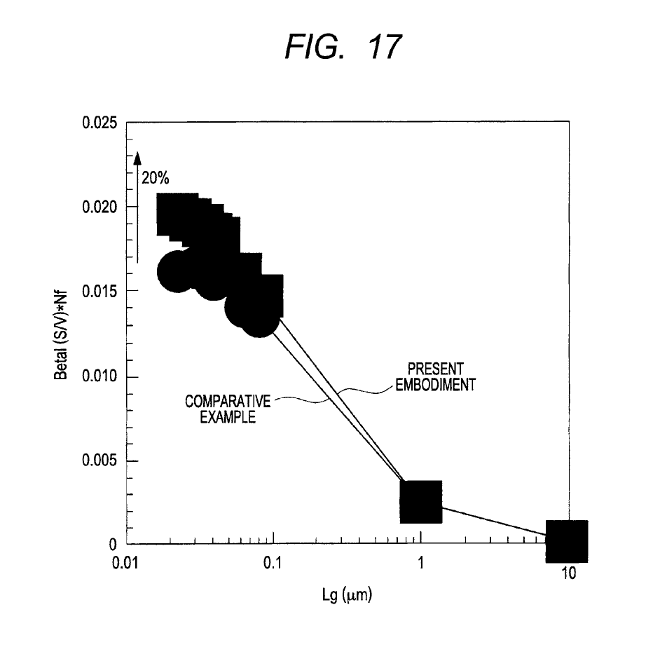

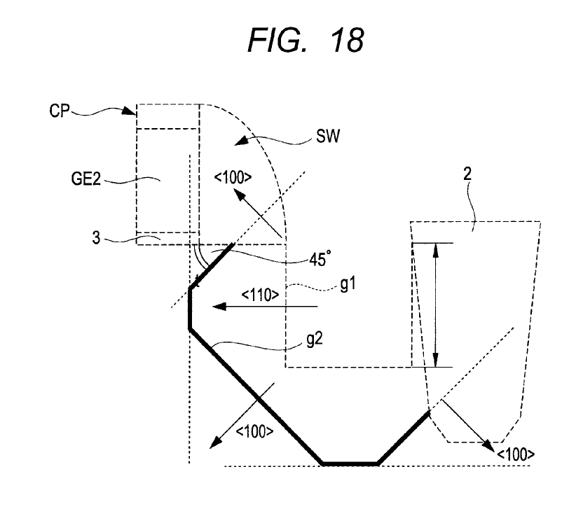

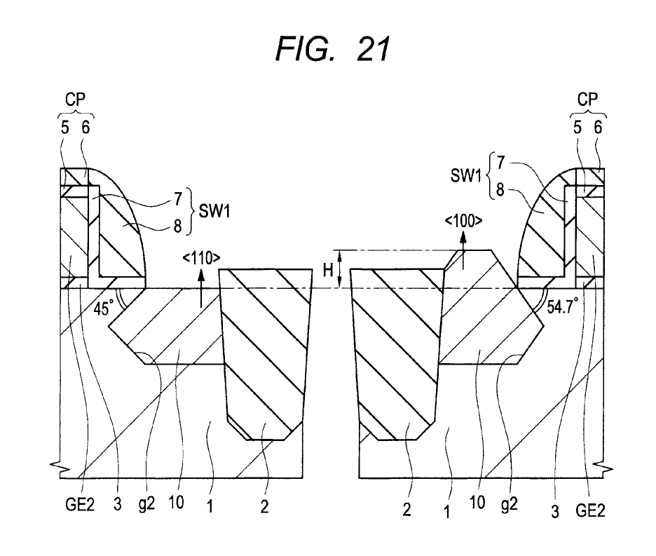

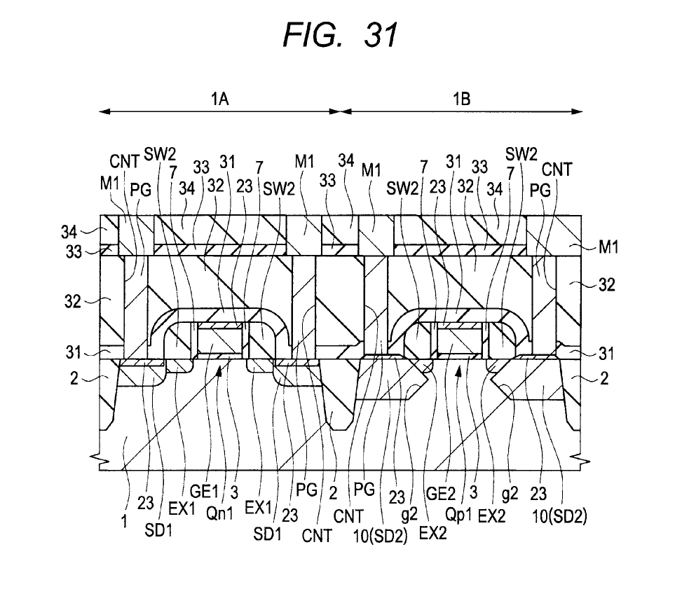

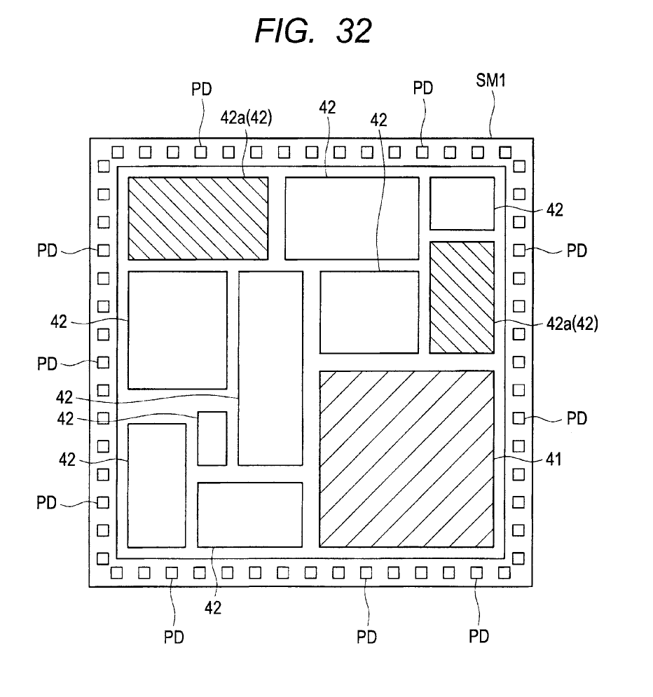

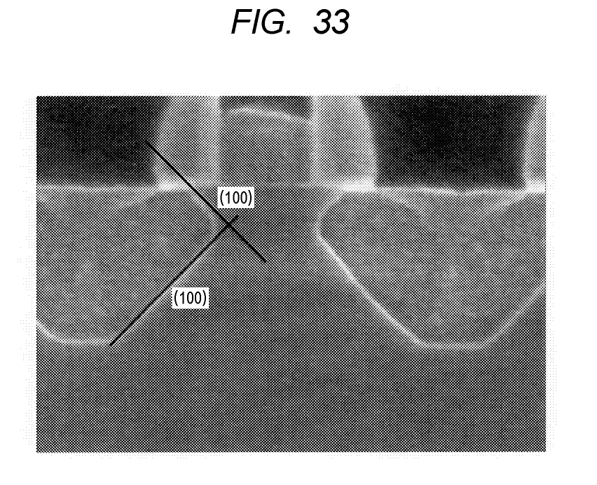

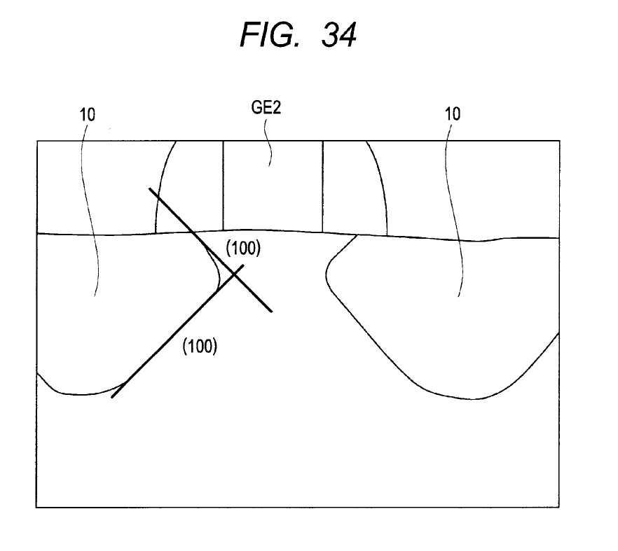

Below, referring to the accompanying drawings, a detailed description will be given to the configuration and the manufacturing method of a semiconductor device of the present embodiment. FIGS. 1 to 6, 19, 20, and 22 to 31 are essential part cross-sectional views each showing a manufacturing step of the semiconductor device of the present embodiment. FIGS. 7, 10, and 11 are cross-sectional views each for illustrating an etching step in manufacturing steps of the semiconductor device of the present embodiment. FIG. 8 is a plan view (top view) for illustrating an etching step in manufacturing steps of the semiconductor device of the present embodiment. FIG. 7 corresponds to, for example, the cross section along A-A of FIG. 8. FIG. 9 is a plan view schematically showing the plane orientation of a silicon substrate 1, and the disposition direction of a gate electrode GE2. FIG. 12 is a view showing the etching direction of the silicon substrate 1. FIG. 13 is a graph showing the relationship between the TMAH treatment time (s) and the recess amount (nm) in each plane orientation of the silicon substrate. FIG. 14 is a cross-sectional view showing an etching step in manufacturing steps of a semiconductor device of Comparative Example. FIG. 15 is a plan view showing the etching step in manufacturing steps of the semiconductor device of Comparative Example. FIG. 16 is a cross-sectional view showing the shape of a trench g2 of the semiconductor device of the present embodiment, and the shape of a trench g2 of the semiconductor device of Comparative Example. FIG. 17 is a graph showing the mobility of holes in p channel type MISFETs in the semiconductor device of the present embodiment and the semiconductor device of Comparative Example. FIG. 18 is an essential part cross-sectional view showing another configuration of the semiconductor device of the present embodiment. FIG. 21 is a cross-sectional view showing the shape of a silicon germanium region 10 of the semiconductor device of the present embodiment and the shape of a silicon germanium region 10 of the semiconductor device of Comparative Example. FIG. 32 is a plan view showing a configuration example of a semiconductor chip using the semiconductor device of the present embodiment. FIG. 33 is a photograph (diagram) showing the cross section of the semiconductor device (p channel type MISFET Qp1) of the present embodiment. FIG. 34 is a reproduced diagram of the photograph (diagram) shown in FIG. 33.

[Structure explanation] First, referring to FIG. 31 which is a cross-sectional view of the final step of the manufacturing steps of the semiconductor device in the present embodiment, a description will be given to the characteristic configuration of the semiconductor device of the present embodiment.

As shown in FIG. 31, the semiconductor device of the present embodiment has an n channel type MISFET Qn1 disposed in an nMIS region 1A of the silicon substrate (semiconductor substrate) 1, and a p channel type MISFET Qp1 disposed in a pMIS region 1B of the silicon substrate 1. The nMIS region 1A and the pMIS region 1B are active regions (active) defined by element isolation regions 2, respectively.

The n channel type MISFET Qn1 has a gate electrode GE1 disposed over the silicon substrate 1 via a gate insulation film 3, and source/drain regions disposed in the silicon substrate 1 on the opposite sides of the gate electrode GE1. The source/drain regions each include an n⁺ type semiconductor region SD1 and an n⁻ type semiconductor region EX1.

The p channel type MISFET Qp1 has a gate electrode GE2 disposed over the silicon substrate 1 via the gate insulation film 3, and source/drain regions disposed in the silicon substrate 1 on the opposite sides of the gate electrode GE2. The source/drain regions each include a p⁺ type semiconductor region SD2(10) and a p⁻ type semiconductor region EX2.

The plane orientation of the silicon substrate 1 is (110). Further, the p⁺ type semiconductor region SD2 forming the source/drain regions of the p channel type MISFET Qp1 is disposed in a silicon germanium region 10.

The silicon germanium region 10 is disposed in the trench g2. The trench g2 has two inclined surfaces at the side surface on the gate electrode GE2 side. A first inclined surface which is one of the two inclined surfaces is an inclined surface extending obliquely from the surface of the silicon substrate 1 downward and in the direction toward the gate electrode GE2. The plane orientation is a (100) plane. Whereas, the other second inclined surface is an inclined surface extending obliquely from the end of the first inclined surface further downward and in the opposite direction from the direction toward the gate electrode GE2 (the direction toward the element isolation region 2). The plane orientation is a (100) plane crossing the (100) plane at an angle of 90°. The two inclined surfaces are situated under a sidewall SW2.

Incidentally, the plane orientation of the bottom surface of the trench g2 is (110). Further, at the side surface of the trench g2 opposite from the gate electrode GE2 side, the side surface of the element isolation region 2 is exposed.

The silicon germanium region 10 is a region resulting from preferential crystal growth from the two inclined surfaces. Such a prescribed crystal plane is referred to as a “facet (crystal habit) plane”. The crystal growth from such a plane may be referred to as “facet growth”.

In other words, each boundary plane between the silicon substrate 1 and the silicon germanium region 10 becomes a (100) plane at the side surface of the silicon germanium region 10, and becomes a (110) plane at the bottom surface of the silicon germanium region 10.

Further, over the silicon germanium region 10, a metal silicide layer 23 is disposed. Further, thereover, a compressive stress film (compression liner film) 31 is formed.

Thus, in accordance with the present embodiment, the silicon substrate 1 with a plane orientation of (110) is used. Therefore, in the p channel type MISFET Qp1, <110> in which the mobility of holes is high can be allowed to serve as the channel. This can improve the characteristics of the p channel type MISFET Qp1.

Further, the silicon germanium regions 10 with a larger lattice constant than that of the silicon substrate 1 are used as the source/drain regions. Therefore, as described in details later, a compressive strain can be applied to the channel region of the p channel type MISFET Qp1. This can improve the characteristics of the p channel type MISFET Qp1. Herein, the lattice constant denotes the length of the side forming the unit cell of the crystal.

Further, the angle formed between the (110) plane of the surface of the silicon substrate 1 and the (100) plane forming the first inclined surface is 45°. Whereas, the angle formed between the (110) plane of the surface of the silicon substrate 1 and the (100) plane forming the second inclined surface is 135°. As a result, the first inclined surface and the second inclined surface come into the bottom side of the sidewall SW2 at a relatively acute angle. Therefore, the compressive strain to be applied to the channel region of the p channel type MISFET Qp1 can be increased.

Further, the silicon germanium region 10 is less likely to undergo crystal growth from the (110) plane which is the plane orientation of the top surface thereof. This improves the flatness between the silicon germanium region 10 and the overlying metal silicide layer 23. As a result, the compressive stress due to the compressive stress film 31 can be effectively applied to the source/drain regions (SD1) of the p channel type MISFET Qp1. This can improve the characteristics of the p channel type MISFET Qp1.

[Manufacturing method explanation] Then, referring to FIGS. 1 to 31, a description will be given to a method for manufacturing the semiconductor device of the present embodiment. In addition, the configuration of the semiconductor device will be made more clear.

First, as shown in FIG. 1, as a semiconductor substrate (semiconductor wafer), the silicon substrate 1 is prepared. Specifically, there is prepared the silicon substrate 1 including p type monocrystalline silicon having a specific resistance of, for example, about 1 to 10 Ω·cm. The plane orientation of the silicon substrate 1 is (110). The plane orientation of (110) means that the surface of the substrate 1 is a (110) plane.

Incidentally, (hkl) represents the Miller indices. (hkl) represents the plane, and <hkl> represents the normal vector with respect to the (hkl) plane. Further, (hkl) represents a plurality of equivalent planes. For example, (100) represents six planes of [100], [010], [001], [−100], [0-10], and [00-1]. Further, <hkl> represents a plurality of equivalent directions. For example, <100> represents six directions of [100], [010], [001], [−100], [0-10], and [00-1].

The silicon substrate 1 has an nMIS region (second region) 1A which is a region where an n channel type MISFET is formed, and a pMIS region (first region) 1B which is a region where a p channel type MISFET is formed.

Then, in the main surface of the silicon substrate 1, an element isolation region 2 is formed. For example, in the silicon substrate 1, there is formed an element isolation trench surrounding the nMIS region 1A and the pMIS region 1B. In the inside of the element isolation trench, an insulation film is embedded. As a result, the element isolation region 2 is formed (see FIG. 8). Such an element isolation method is referred to as a STI (Shallow Trench Isolation) method. Other than this, the element isolation region 2 may be formed using the LOCOS (Local Oxidization of Silicon) method.

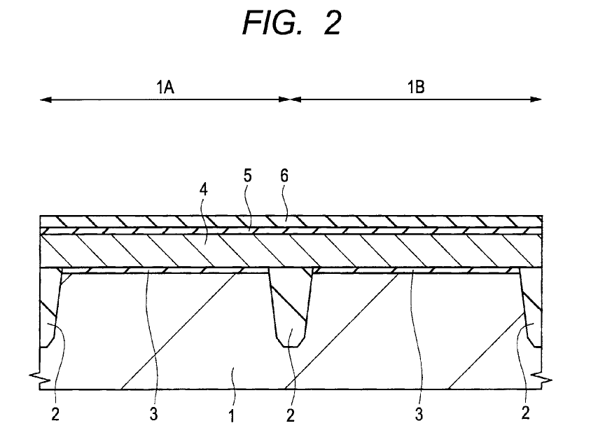

Then, by wet etching using, for example, a hydrofluoric acid (HF) aqueous solution, the surface of the silicon substrate 1 is purified (cleaned). Then, as shown in FIG. 2, over the surface of the silicon substrate 1, as a gate insulation film 3, for example, a thin silicon oxide film is formed by a thermal oxidation method. Then, over the gate insulation film 3, as a conductive film, a silicon film 4 is formed with a film thickness of about 50 to 150 nm using, for example, a CVD (Chemical Vapor Deposition) method. As the silicon film 4, for example, an impurities-containing polycrystal silicon film (a doped polysilicon film) can be used. Alternatively, during deposition, an amorphous silicon film may be formed to be made polycrystalline by a heat treatment. As the heat treatment, for example, there can be used activation annealing of impurities introduced for forming the source/drain regions. Still alternatively, after formation of a silicon film not containing impurities, impurities may be injected by an ion implantation method.

Then, over the silicon film 4, as an insulation film, a silicon oxide film 5 is formed. Over the silicon oxide film 5, as an insulation film, a silicon nitride film 6 is formed. The silicon oxide film 5 and the silicon nitride film 6 can be formed using, for example a CVD method. The film thickness (deposited film thickness) of the silicon oxide film 5 can be set at, for example, about 2 to 8 nm. The film thickness (deposited film thickness) of the silicon nitride film 6 can be set at, for example, about 10 to 60 nm.

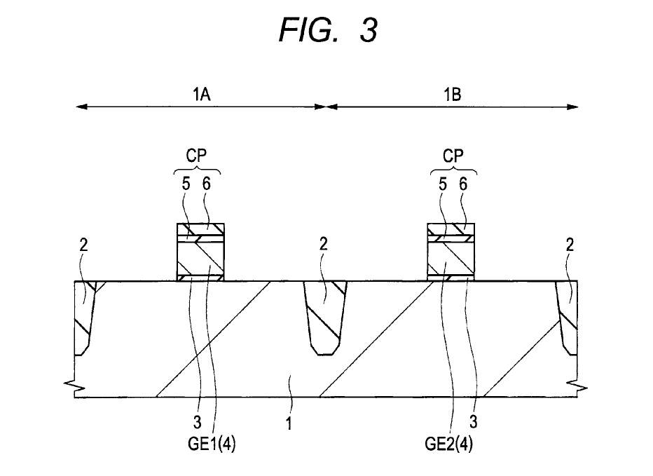

Then, as shown in FIG. 3, over a lamination film of the silicon film 4, the silicon oxide film 5, and the silicon nitride film 6, a photoresist film not shown is formed. Thus, exposure/development (photolithography) is performed. As a result, in prescribed regions (herein, gate electrodes GE1 and GE2 forming regions), the photoresist film is left. Then, with the remaining photoresist film as a mask, the lamination film is etched, and the photoresist film is removed. Below, such a step of forming a film in a prescribed planar shape, and performing etching (selective removal) with the film as a mask, and thereby forming a film (pattern) in a desired planar shape will be referred to as patterning. By the patterning step, a gate electrode GE1 including the silicon film 4 is formed in the nMIS region 1A, and a gate electrode GE2 including the silicon film 4 is formed in the pMIS region 1B. Over the gate electrodes GE1 and GE2, there are disposed cap insulation films CP each including a lamination film of the silicon oxide film 5 and the silicon nitride film 6, respectively.

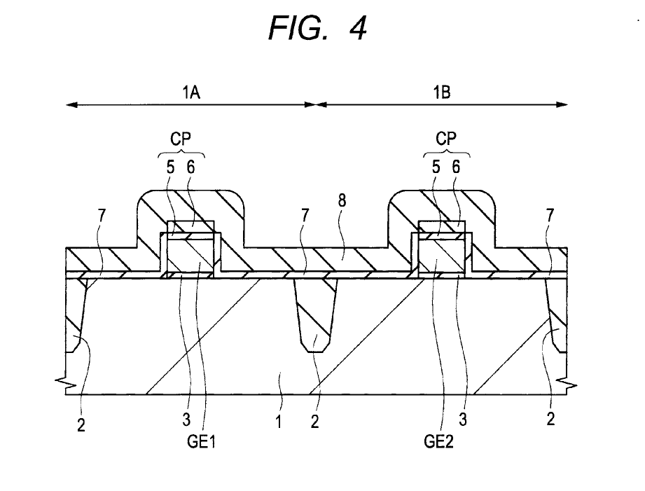

Then, as shown in FIG. 4, over the main surface of the silicon substrate 1 including over the sidewalls of the gate electrodes GE1 and GE2, as an insulation film, for example, a silicon oxide film 7 is formed. The silicon oxide film 7 is formed with a film thickness of about 4 to 20 nm by, for example, a thermal oxidation method. The silicon oxide film 7 may be formed by a CVD method. In this case, the silicon oxide film 7 is also formed over the silicon nitride film 6.

Then, over the silicon oxide film 7 and the silicon nitride film 6, as an insulation film, a silicon nitride film 8 is formed. The silicon nitride film 8 is stacked with a film thickness necessary for forming a sidewall described later, such as a film thickness of about 50 nm, using for example, a CVD method.

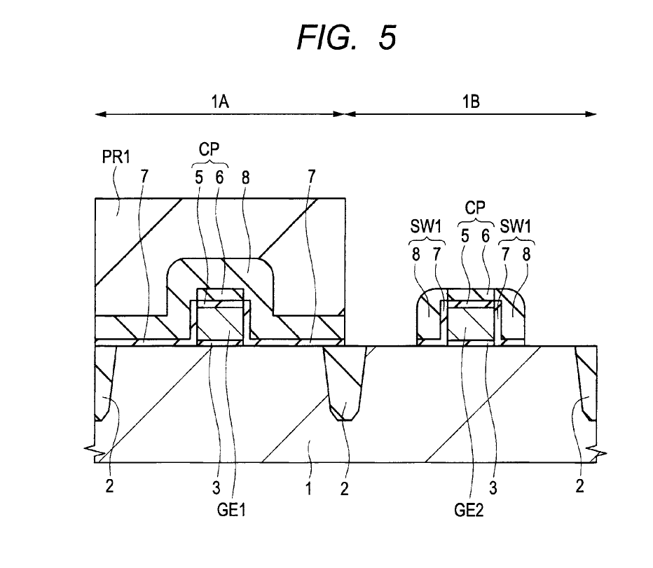

Then, as shown in FIG. 5, over the silicon nitride film 8, a photoresist film is applied. The photoresist film is subjected to exposure and development. As a result, a photoresist film PR1 is left in such a manner as to cover the nMIS region 1A.

Then, the silicon nitride film 8 and the silicon oxide film 7 in the pMIS region 1B are anisotropically etched (etched back). As a result, at each sidewall part of the gate electrode GE2 in the pMIS region 1B, there is formed a sidewall (sidewall insulation film, sidewall spacer) SW1 including the silicon oxide film 7 and the silicon nitride film 8. Then, the photoresist film PR1 is removed.

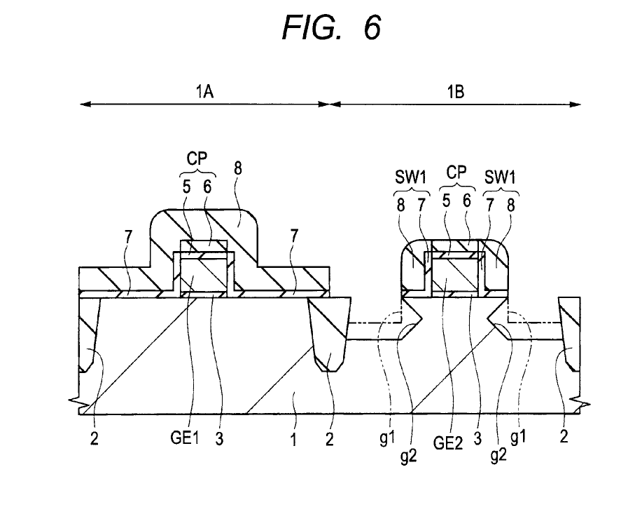

Then, as shown in FIG. 6, in the pMIS region 1B, with the silicon nitride film 6 over the gate electrode GE2 and the sidewall SW1 as a mask, etching is performed. As a result, in the silicon substrate 1 on the opposite sides of the synthetic pattern of the gate electrode GE2 and the sidewall SW1, a trench g2 is formed. The etching is performed by two-step etching. By first etching, the trench g1 is formed, then, further, second etching is performed to form the trench g2.

<Explanation of First and Second Etching Steps>

Below, referring to FIGS. 7 to 18, the first etching step and the second etching step will be described. Incidentally, in FIG. 6 and the like, the surface of the element isolation region 2 and the surface of the silicon substrate 1 are shown at the comparable positions. However, various treatments cause a difference in height therebetween. In FIG. 7 and the like, the difference in height is clearly shown.

<1> Explanation of shape of each constituent part before first etching First, referring to FIGS. 7 and 8, a description will be given to the shapes of the sidewall (the silicon oxide film 7 and the silicon nitride film 8) SW1, and the cap insulation film over the gate electrode GE2 (the lamination film including the silicon oxide film 5 and the silicon nitride film 6) CP serving as the mask of the etching.

As shown in FIG. 7 (cross-sectional view), at each sidewall part of the gate electrode GE2, the sidewall SW1 is situated. Over the gate electrode GE2, the cap insulation film CP is situated. Accordingly, the gate electrode GE2 is covered with the sidewall SW1 and the cap insulation film CP. With the sidewall SW1 and the cap insulation film CP as a mask, etching is performed. Thus, the portion of the silicon substrate 1 exposed from each end of the sidewall SW1 is etched. As a result, the trenches (g1 and g2) are formed.

Further, as shown in FIG. 8 (plan view), the pMIS region 1B in which the p channel type MISFET Qp1 is formed is an exposed region (active region) of the silicon substrate 1 surrounded by the element isolation region 2. Herein, the planar shape (the shape or pattern as seen from the top) is shown as a generally first rectangular region a. The long sides of the first rectangle extend in the x direction, and the short sides extend in the y direction. Also apparent from FIG. 9, herein, the x direction is the <110> direction, and the y direction is the <100> direction. Incidentally, the <110> direction of the x direction is the direction of channel length. Namely, it is the direction of a current passing between the source and the drain when the p channel type MISFET Qp1 is rendered in an ON state.

The planar shape of the gate electrode GE2 is a generally second rectangular shape, and is disposed in the generally central part of the region a. The short sides of the second rectangle extend in the x direction (<110> direction), and the long sides extend in the y direction (<100> direction). While the long sides of the second rectangle extend in such a manner as to cross the region a, the short sides extend over the element isolation region 2. Further, the planar shape of the cap insulation film CP over the gate electrode GE2 is also a general second rectangle.

The synthetic planar shape of the cap insulation film CP and the sidewall SW1 is a general third rectangle a size larger than the second rectangle. The short sides of the third rectangle extend in the x direction (<110> direction), and the long sides extend in the y direction (<100> direction). While the long sides of the third rectangle extend in such a manner as to cross the region a, the short sides extend over the element isolation region 2.

On the opposite sides of the third rectangle, as the exposed regions of the silicon substrate 1, general fourth rectangular regions e1 and e2 are disposed, respectively. In the region e1, the trench (g1, g2) is formed. In the region e2, the trench (g1, g2) is formed. The long sides (ends) of the regions e1 and e2 on the gate electrode GE2 side extend in the y direction (<100> direction). As described in details later, the first inclined surfaces of the trenches g2 extend obliquely from the long sides (ends) of the regions e1 and e2 on the gate electrode GE2 side downward and in the direction toward the gate electrode GE2.

Incidentally, FIG. 9 schematically shows the plane orientation of the silicon substrate 1 and the disposition direction of the gate electrode GE2. It is naturally understood that the gate electrode GE2 and the like are each disposed in a very minute shape relative to the size of the silicon substrate 1. Further, the plan view shown in FIG. 8 is one example. The shape of the active region and the layout of the gate electrode GE2 can be variously changed. For example, the shape of the active region may be an L-shape or the like. Alternatively, when the gate electrode GE2 is routed in order to be coupled with a gate electrode of another MISFET, the planar shape of the gate electrode GE2 may include some portions extending in other directions than the <100> direction.

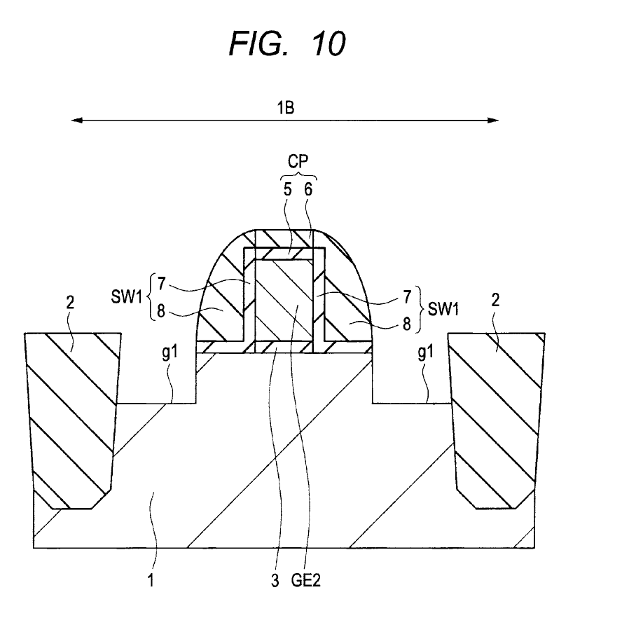

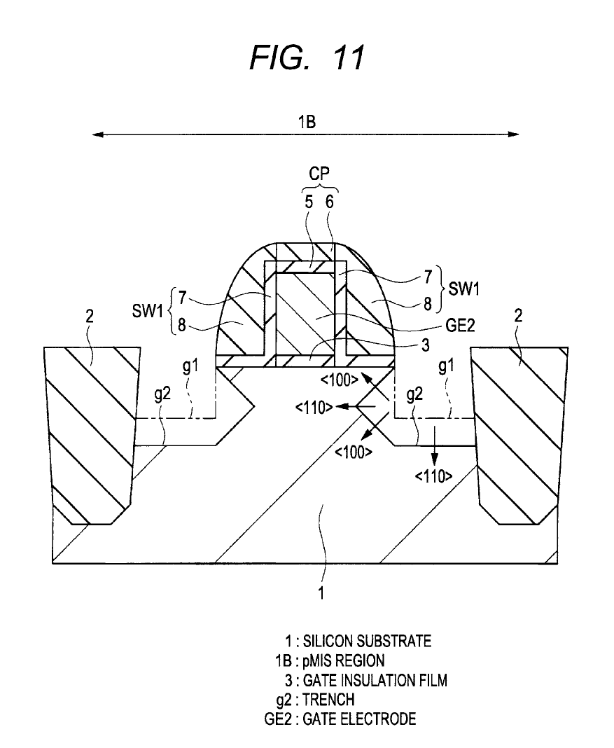

Then, a description will be given to a step of etching the silicon substrate 1 (regions e1 and e2) on the opposite sides of the synthetic pattern of the gate electrode GE2 and the sidewall SW1 with the sidewall SW1 and the cap insulation film CP in the foregoing shape as a mask.

<2> Explanation of first etching step First, first etching is performed. Specifically, as shown in FIG. 10, in the pMIS region 1B, the silicon substrate 1 on the opposite sides of the synthetic pattern of the gate electrode GE2 and the sidewall SW1 is etched from the surface thereof to a prescribed depth. As a result, each trench (substrate recess part, substrate retreated par) g1 is formed. The first etching is performed by anisotropic dry etching, thereby to change the trench shape into a general box shape. For example, the depth of the trench is set at about 30 nm to 50 nm. The type of the plasma gas is, for example, a mixed gas plasma of HBr, CF₄, and O₂. The pressure is, for example, 0.4 Pa. By the first etching, on the gate electrode GE2 side of the trench g1, the first side surface is exposed. On the element isolation region 2 side, the second side surface is exposed. Herein, as the second side surface, the sidewall of the element isolation region 2 is exposed. The surface of the silicon substrate 1 is, as described above, the (110) plane. Accordingly, at the first side surface of the trench g1 on the gate electrode GE2 side, the (110) plane of the silicon substrate 1 is exposed. At the bottom surface, the (110) plane of the silicon substrate 1 is exposed.

<3> Explanation of second etching step Then, second etching is performed. Specifically, as shown in FIG. 11, the silicon substrate 1 exposed from the bottom surface of each trench g1 is further retreated by about 30 nm to 50 nm. At this step, from the first side surface of each trench g1, as shown in FIG. 12, etching proceeds in the oblique direction. The oblique direction is the <100> direction.

The second etching is performed by anisotropic wet etching. The anisotropic wet etching represents an etching technology of exposing a prescribed crystal plane using the difference in etching rate according to the crystal plane of silicon when etching is performed using an etchant (chemical). As the etchants, for example, there can be used TMAH (Tetramethyl ammonium hydroxide; N(CH₃)₄OH) type etchants.

For example, using an ultrapure water-diluted solution containing TMAH in an amount of 2.38 wt %, anisotropic wet etching is performed at 23° C. Such an etching step can increase the etching rate of the (110) plane.

Incidentally, for the concentration of TMAH, there can be used a 25-wt % or less, more preferably, 3-wt % or less solution. Such a solution is preferable because anisotropy is revealed remarkably particularly in a low concentration. Whereas, as the solvents of the etchant, there can be used other solvents than water. Further, additives may be appropriately added.

FIG. 13 is a graph showing the relationship between the TMAH treatment time (s) and the recess amount (nm) in each plane orientation of the silicon substrate 1. As shown in FIG. 13, in the silicon crystal, the etching rate varies according to the plane orientation. For all the (111) plane, the (100) plane, and the (110) plane, an increase in treatment time results in an increase in recess amount (etching amount). However, the respective slopes are 0.0419 for the (111) plane, 0.4182 for the (100) plane, and 0.901 for the (110) plane. This indicates that the (110) plane, the (100) plane, and the (111) plane decrease in susceptibility to etching in this order. In other words, it is indicated as follows: for the etching rate (recess amount/TMAH treatment time), there is the relationship of “the etching rate of the (111) plane<<the etching rate of the (100) plane<<the etching rate of the (110) plane”. Incidentally, the intercept (40 nm) of each graph in FIG. 13 represents the depth of the trench g1 in first etching.

Accordingly, when the anisotropic wet etching is used as second etching, as shown in FIG. 12, in the (110) plane which is the first side surface of the silicon substrate 1, etching proceeds in a first direction and in a second direction crossing the first direction. As a result, two inclined surfaces are exposed. Namely, the first side surface of the trench g1 is retreated. Thus, there is exposed the side surface having a first inclined surface, and a second inclined surface crossing the first inclined surface forming the first side surface of the trench g2 on the gate electrode GE2 side.

Specifically, etching proceeds in the <100> direction and in the <100> direction crossing the <100> direction at an angle of 90° (see FIG. 12). This results in the formation of the first side surface of the trench g2 on the gate electrode GE2 side, having the (100) plane, and the (100) plane crossing the (100) plane at an angle of 90° (see FIGS. 11 and 12).

A further detailed description will be given to the plane orientations of the two inclined surfaces. The first inclined surface which is one of the two inclined surfaces is an inclined surface extending obliquely from the surface of the silicon substrate 1 downward and in the direction toward the gate electrode GE2. The plane orientation thereof is the (100) plane. Whereas, the other second inclined surface is an inclined surface extending obliquely from the end of the first inclined surface further downward and in the opposite direction from the direction toward the gate electrode GE2 (the direction toward the element isolation region 2). The plane orientation thereof is the (100) plane crossing the (100) plane at an angle of 90°. The two inclined surfaces are situated under the sidewall SW1.

Namely, the angle formed between the (100) plane forming the first inclined surface and the (110) plane of the surface of the silicon substrate 1 is 45°. The angle formed between the (100) plane forming the first inclined surface and the first side surface of the trench g1 ((110) plane perpendicular to the surface of the silicon substrate 1) is 45° (see FIG. 12). Whereas, the angle formed between the (100) plane forming the second inclined surface and the (110) plane of the surface of the silicon substrate 1 is 135°. The angle formed between the (100) plane forming the second inclined surface and the first side surface of the trench g1 (the (110) plane perpendicular to the surface of the silicon substrate 1) is 135° (see FIG. 12). In other words, the first inclined surface crosses the (110) plane at an angle thereabove of 45°. The second inclined surface crosses the (110) plane at an angle formed therebelow of 45°.

With the configuration of the first inclined surface and the second inclined surface described in details up to this point, the first inclined surface and the second inclined surface come into the bottom side of the sidewall SW1 at a relatively acute angle. For this reason, the compressive strain to be applied to the channel region of the p channel type MISFET Qp1 can be increased. Incidentally, in the following description (including the description after the second embodiment), the configuration of the first inclined surface and the second inclined surface may be simply referred to as “a (100) plane, and a (100) plane crossing the (100) plane at an angle of 90°.

On the other hand, although the bottom surface of the trench g2 is retreated from the bottom surface of the trench g1, the plane orientation thereof is still (110). Incidentally, the trench shape having such two inclined surfaces may be referred to as a Σ shape (sigma shape).

Thus, in accordance with the present embodiment, it is possible to form the trench g2 in the Σ shape. Accordingly, by epitaxial growth of silicon germanium in the inside of the trench g2 described in details later, a compressive strain can be applied to the channel region of the p channel type MISFET. This can improve the operation characteristics. Incidentally, herein, the first inclined surface and the second inclined surface are formed with a TMAH solution. However, the planes are the (100) planes at a microscopic atomic level. However, in actuality, slight displacement occurs as a whole, so that a maximum displacement of about ±3° may occur with respect to the theoretical angle (e.g., the formed angle of 45° or the formed angle of 135°).

<4> Explanation of Effect of SiGe Strain Technology

The silicon germanium region 10 causes a compressive strain to act on (to be applied to) the channel region of the p channel type MISFET Qp1 (the substrate region immediately under the gate electrode GE2). This can increase the mobility of holes (the mobility of holes in the channel region) (the technology is referred to as a SiGe strain technology). As a result, it is possible to increase the on current passing through the channel of the p channel type MISFET Qp1, which can implement a higher speed operation.

The silicon germanium region 10 causes a compressive stress to act on the channel region. This is mainly due to the fact that the lattice constant of silicon germanium (the silicon germanium region 10) is larger than the lattice constant of silicon (silicon substrate 1).

Further, when the SiGe strain technology as described above is used, it is preferable to use a <110> channel with a high sensitivity of mobility (mobility of holes) to strain. Namely, the change amount of the mobility of holes when the channel region is strained by a compressive stress is higher in <110> direction than in other directions. Accordingly, in order to attain the improvement of the mobility by the SiGe strain technology and the improvement of the on current caused thereby, it is preferable to use the <110> channel.

Herein, the <110> channel corresponds to the fact that the gate length direction of the channel region is the <110> direction of the silicon substrate 1 (see FIG. 9). Thus, the channel region of the p channel type MISFET is set to be the <110> channel. This can enhance the effect of improving the mobility of holes, which can enhance the effect of improving the on current.

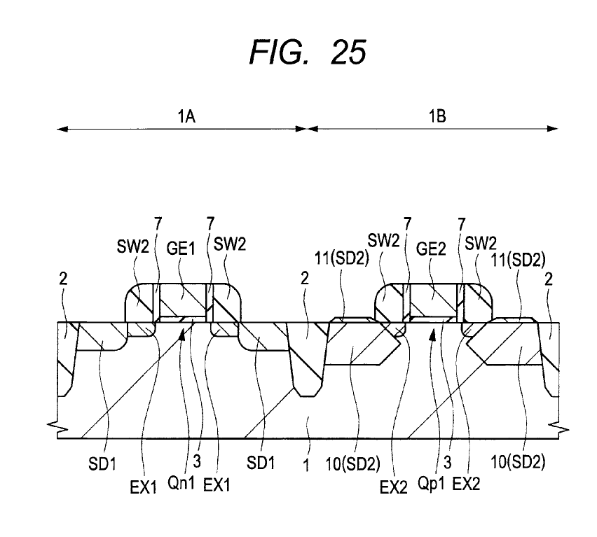

On the other hand, it is preferable that the foregoing SiGe strain technology is not applied to the n channel type MISFET Qn1. This is due to the following fact. In the n channel type MISFET Qn1, when a compressive stress acts on the channel region, the mobility of electrons which are carriers is rather reduced. For this reason, the nMIS region 1A is covered with the silicon nitride film 8 (see FIG. 6), and the trench g2 is not formed. Thus, as described later, source/drain regions including silicon (n⁺ type semiconductor regions SD1) are formed (see FIG. 25).

Thus, the foregoing SiGe strain technology is applied to the p channel type MISFET Qp1, and the foregoing SiGe strain technology is not applied to the n channel type MISFET Qn1. As a result, it is possible to improve the mobility of holes in the channel region of the p channel type MISFET Qp1 without reducing the mobility of electrons in the channel region of the n channel type MISFET Qn1. Therefore, it becomes possible to improve the on current of the p channel type MISFET Qp1 without reducing the on current of the n channel type MISFET Qn1.

<5> Explanation of Effect Resulting from the Fact that the First Side Surface of the Trench g2 has a (100) Plane, and a (100) Plane Crossing the (100) Plane at an Angle of 90°

Further, in the case of the present embodiment, the angle formed between the surface (110) plane of the silicon substrate 1 and the (100) plane is 45°. This results in that the first inclined surface comes into the bottom side of the sidewall SW1 at a relatively acute angle. Accordingly, a compressive stain can be more effectively applied to the channel region of the p channel type MISFET.

Then, the effect will be further described in details in comparison with Comparative Example. FIG. 14 is a cross-sectional view showing an etching step in manufacturing steps of a semiconductor device of Comparative Example. FIG. 15 is a plan view for illustrating the etching step in the manufacturing steps of the semiconductor device of Comparative Example. FIG. 14 corresponds to, for example, a cross-section along A-A of FIG. 15. FIG. 16 is a cross-sectional view showing the shape of the trench g2 of the semiconductor device of the present embodiment and the shape of the trench g2 of the semiconductor device of Comparative Example.

In the semiconductor device of Comparative Example shown in FIG. 14, using the silicon substrate 1 with a plane orientation of (100), the gate electrode GE2 and the sidewall SW1 are formed through the same manufacturing steps as those of the present embodiment. In the comparative example, as shown in FIG. 15, the sidewall SW1 and the gate electrode GE2 extend in the <110> direction in the active region.

In the comparative example, the first etching step was performed in the same manner as in the present embodiment. Then, as the second etching step, using aqueous ammonia (NH₄OH) diluted to 100 times as an etchant, wet etching was performed at 50° C.

In this case, as shown in FIG. 14, at the first side surface of the trench g2 on the gate electrode GE2 side, there are formed a (111) plane, and a (111) plane crossing the (111) plane. Incidentally, the plane orientation of the bottom surface of the trench g2 is (100).

Thus, also in the manufacturing steps of the semiconductor device of Comparative Example, in the trench g2, the two inclined surfaces are formed. However, the plane orientation thereof is the (111) plane. The (111) plane is a plane crossing the surface (110) plane of the silicon substrate 1 at about 54.7°.

Accordingly, as shown in FIG. 16, in the semiconductor device of the comparative example (the lower diagram), as compared with the upper diagram showing that of the present embodiment, the recess amount in the direction of the side surface of the trench g2 is smaller by the distance t.

Thus, in the present embodiment, the recess amount can be set larger. This can increase the compressive strain to the channel region of the p channel type MISFET. coefficients serving as the indices of the mobility of holes in the p channel type MISFETs in the semiconductor device of the present embodiment and the semiconductor device of Comparative Example not having an inclined surface of the Si(100) plane. The abscissa represents the gate length (μm), and the ordinate represents the transistor driving coefficient. As shown in FIG. 17, it has been shown that in the semiconductor device of the present embodiment, the mobility is improved than that of the semiconductor device of Comparative Example by about 20%.

Incidentally, in FIGS. 11 and 16 (upper diagram), it is shown that, at the first side surface of the trench g2 on the gate electrode GE2 side, a (100) plane and a (100) plane crossing the (100) plane cross each other perpendicularly. However, exposure of the crystal plane is not necessarily in such an ideal state. Particularly, at the boundary between the crystal planes, the manner in which the crystal plane is exposed often changes. Accordingly, when there are at least planes at which a (100) plane and a (100) plane crossing the (100) plane are exposed in the first side surface, the inclined surfaces are formed at a relatively acute angle. This produces the effect. For example, as shown in FIG. 18, in the first side surface of the trench g2 on the gate electrode GE2 side, at the boundary between the first inclined surface which is a (100) plane, and the second inclined surface which is a (100) plane crossing the (100) plane, the (110) plane may be exposed.

<Explanation of Growth Step of SiGe>

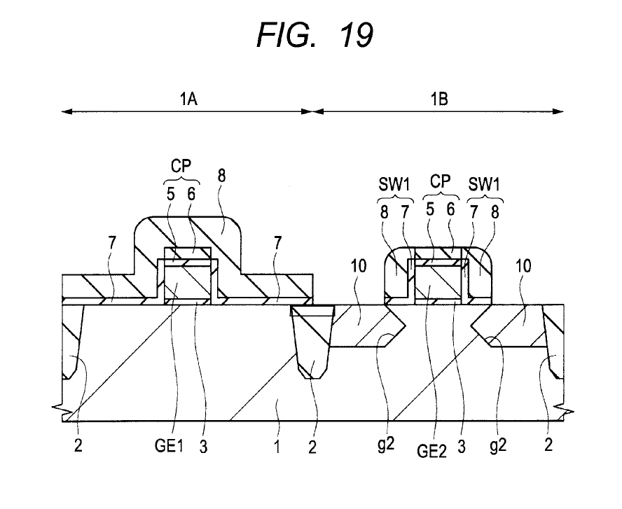

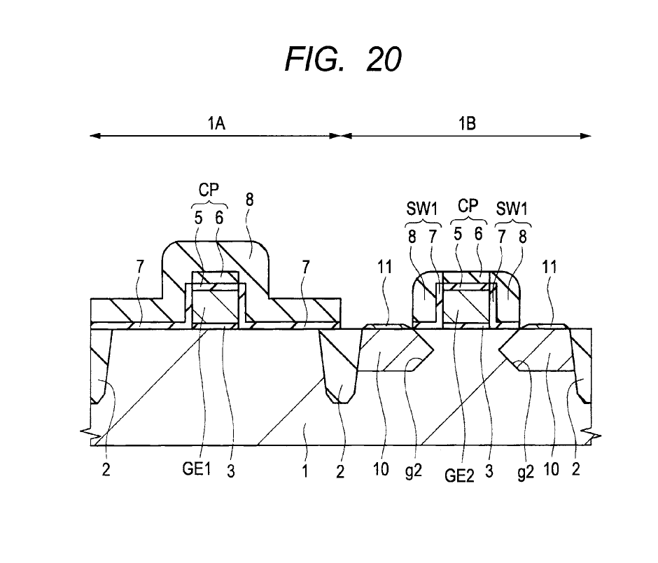

Then, as shown in FIG. 19, in the trench g2 in the pMIS region 1B, silicon germanium (SiGe) is epitaxially grown (crystal grown). Si (silicon substrate 1) and SiGe are analogous in lattice constant to each other. Accordingly, only adjustment of the raw material gases in the gas epitaxy method enables the deposition as continuous crystals. The silicon germanium is grown until the inside of the trench g2 is filled thereby. Thus, the silicon germanium region (SiGe region, silicon germanium layer, epitaxial silicon germanium layer) 10 is formed. Further, over the silicon germanium region 10, silicon (Si) is continuously epitaxially grown. As shown in FIG. 20, a silicon region (silicon layer, epitaxial silicon layer) 11 is formed. The silicon germanium region 10 can include, for example, 60 to 80 at % Si and 20 to 40 at % Ge by changing the flow rate ratio of the raw material gases (silane series gas and germane series gas). Namely, when the gas is expressed as Si₁₋ₓGeₓ, it can be set that 0.2≦x≦0.4.

The silicon germanium region 10 can be formed by epitaxial growth using, for example, a silane series gas and a germane series gas as raw material gases. As the silane series gases, there can be used, for example, monosilane gas (SiH₄) and dichlorosilane (SiH₂Cl₂). Whereas, as the germane series gases, monogermane gas (GeH₄) and the like can be used. Further, by adjusting the ratio of the supply amount (flow rate) of the germane series gas to the supply amount of the silane series gas, it is possible to change the concentration (ratio, composition ratio) of Ge in the silicon germanium region 10. The silicon germanium region 10 can be formed with a thickness of, for example, about 40 to 100 nm. The silicon region 11 can be formed with a thickness of, for example, about 5 to 20 nm. Herein, deposition is performed with a p type doping gas (gas for adding p type impurities) such as boron hydride (B₂H₆) contained in the raw material gases. As a result, the p type silicon germanium region 10 is formed. Thus, by performing deposition so as to allow the p type silicon germanium region to contain p type doping gases, it is possible to form the source/drain regions of the p channel type MISFET (Qp1) with high precision without ion implantation. Further, the silicon region 11 is formed over the silicon germanium region 10. As a result, it is possible to form silicide formed by the salicide technology described later with precision. For silicon germanium, the history of adoption thereof is shallow, and the compatibility with other technologies is not established very much. For any silicon, technologies of forming silicide on the surface thereof have been accumulated, which enables formation of silicide with good compatibility. Incidentally, after deposition of a non-doped silicon germanium region 10, p type impurity ions may be injected by an ion implantation method. The ion implantation step will be described later.

There will be shown one example of the epitaxial growth conditions of the silicon germanium region 10 and the silicon region 11. For the formation of the silicon germanium region 10, for example, in a reaction chamber (chamber), under a 700° C. and 1.33 kPa atmosphere, as the raw material gases, dichlorosilane, monogermane gas, and boron hydride (B₂H₆) are introduced at flow rates of 20 sccm, 15 sccm, and 160 sccm, respectively, together with hydrochloric acid (HCl) at a flow rate of 23 ccm which is a carrier gas. When silicon germanium is epitaxially grown under such conditions, the amount of Ge in terms of atomic percent is about 20%, and the amount of Si in terms of atomic percent is about 80%. Namely, when silicon germanium is expressed as Si₁₋ₓGeₓ, x≈0.2. Incidentally, 1 Pa=1N/m², sccm (standard cc/min) represents the amount (cc=cm³) of a gas to be introduced per minute. Whereas, for the formation of the silicon region 11, for example, in a reaction chamber (chamber), under a 725° C. and 1.33 kPa atmosphere, as the raw material gases, dichlorosilane is introduced at a flow rate of 20 sccm together with hydrochloric acid at a flow rate of 17 sccm which is a carrier gas.

Herein, in the present embodiment, crystal growth preferentially proceeds from a (100) plane, and a (100) plane crossing the (100) plane at an angle of 90° of the trench g2. In other words, for the crystal growth, there is established the opposite relationship from the relationship of the etching rate (etching rate of (111) plane<<etching rate of (100) plane<<etching rate of (110) plane). For the ease of crystal growth, i.e., the rate of crystal growth, there is the relationship of “crystal growth rate of (111) plane>> crystal growth rate of (100) plane>> crystal growth rate of (110) plane”. Accordingly, since the bottom surface of the trench g2 is the (110) plane, crystal growth preferentially proceeds from a (100) plane, and a (100) plane crossing the (100) plane at an angle of 90° of the side surface of the trench g2. Further, as a result of the crystal growth, the surface of the silicon germanium region 10 becomes the (110) plane. Accordingly, crystal growth is less likely to occur from the surface in the perpendicular direction. This results in the improvement of the flatness of the surface of the silicon germanium region 10.

FIG. 21 is a cross-sectional view showing the shape of the silicon germanium region 10 of the semiconductor device of the present embodiment, and the shape of the silicon germanium region 10 of the semiconductor device of Comparative Example. As shown in the right-hand side diagram of FIG. 21, in the comparative example, when the silicon germanium region 10 is formed inside the trench g2, the surface of the silicon germanium region 10 becomes the (100) plane from which crystal growth tends to occur. For this reason, crystal grows both from the surface and in the perpendicular direction at all times. Thus, the surface of the silicon germanium region 10 gradually rises to be higher than the surface of the silicon substrate 1. The height (rising amount) of the surface of the silicon germanium region 10 from the surface of the silicon substrate 1 is referred to as H. Thus, in the comparative example, the surface of the silicon germanium region is in a convex shape.

In contrast, in the present embodiment, as described above, the flatness of the surface of the silicon germanium region 10 is improved. Namely, as shown in the left-hand side diagram of FIG. 21, in the present embodiment, the surface of the silicon germanium region 10 becomes the (110) plane from which crystal growth is less likely to occur. For this reason, the rising amount can be reduced. Accordingly, as described above, the flatness of the surface of the silicon germanium region 10 is improved. For example, the surface (top surface) of the silicon germanium region 10 can be formed at a position lower than the surface (top surface) of the gate insulation film 3.

Further, similarly for the silicon region 11 grown over the silicon germanium region 10, crystal growth is less likely to occur from the (100) plane. Accordingly, similarly for the silicon region 11, the flatness is improved.

As a result, a stress due to a compressive stress film (31) described later becomes more likely to be applied to the silicon germanium region 10. This can further improve the characteristics of the p channel type MISFET Qp1. Further, deposition control is also facilitated, which enables the formation of the top surface of the silicon germanium region 10 at a position lower than the top surface of the gate insulation film 3.

Further, the height (rising amount) H of the convex shape in Comparative Example in FIG. 21 may vary according to the density of elements (loading effect). Namely, in the region where p channel type MISFETs Qp1 are sparse, the supply amount of the raw material gases due to epitaxial growth increases. Accordingly, the rising amount H tends to be increased. On the other hand, in the region where p channel type MISFETs Qp1 are dense, the supply gases are distributed among a plurality of elements. For this reason, the rising amount H is reduced. Thus, in the semiconductor device of Comparative Example, the rising amount H of the silicon germanium region 10 tends to vary, so that control of epitaxial growth becomes difficult.

In contrast, in the semiconductor device of the present embodiment, the surface of the silicon germanium region 10 becomes the (110) plane at which crystal growth is less likely to occur. This enables the self stop of epitaxial growth, so that the controllability of the epitaxial growth is improved. Further, it is possible to reduce the variation in rising amount H of the silicon germanium region 10. Incidentally, the self stop means that, after filling of the silicon germanium region 10 in the trench g2, the rate of epitaxial growth from the surface is reduced. However, the self stop does not mean the complete stop of epitaxial growth.

Further, similarly for the silicon region (11) to grow over the silicon germanium region 10, crystal growth is less likely to occur from the (100) plane. Accordingly, similarly for the silicon region 11, the controllability is improved for the epitaxial growth. Further, it is possible to reduce the variation in surface height (top surface height) of the silicon region 11. Therefore, with respect to the p channel type MISFET Qp1 in any region, a compressive stress due to the compressive stress film (31) can be applied to the source/drain regions (SD1) of the p channel type MISFET Qp1 with less variations.

Incidentally, in the epitaxial growth steps of the silicon germanium and the silicon, other regions than the trench g2 are covered with the silicon nitride film 6, the sidewall SW1, or the silicon nitride film 8. For this reason, the silicon germanium region 10 (and the overlying silicon region 11) is not formed. Therefore, the silicon germanium region 10 (and the overlying silicon region 11) is (are) formed in the pMIS region 1B, but not formed in the nMIS region 1A.

Then, the surface layer part of the silicon region 11 is oxidized by a thermal oxidation method or the like. As a result, over the surface of the silicon region 11, a silicon oxide film (not shown) is formed. The silicon oxide film has a role as an etching protective film for preventing etching of the silicon region 11 or the silicon germanium region 10 during removal of the silicon nitride film 8 described later.

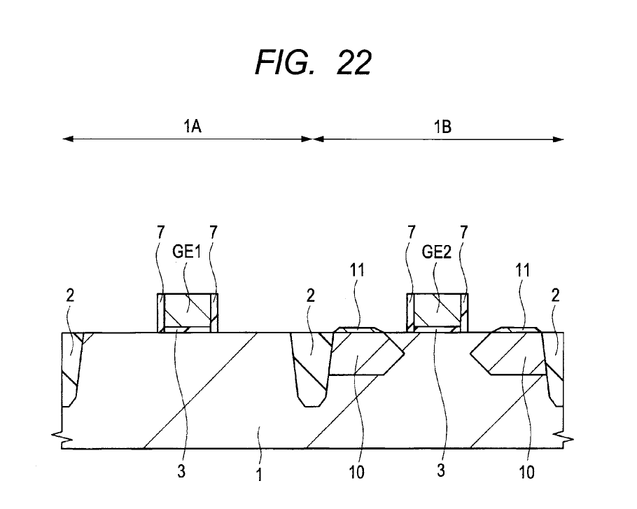

Then, as shown in FIG. 22, using hot phosphoric acid or the like, the silicon nitride film 8 in the nMIS region 1A and the silicon nitride film 8 of the sidewall SW1 in the pMIS region 1B are etched and removed. In this step, the silicon nitride film 6 over the gate electrodes GE1 and GE2 may also be removed.

Then, the silicon oxide film 7 is removed by etching. Herein, anisotropic etching is performed, so that the silicon oxide film 7 is left at each sidewall of the gate electrodes GE1 and GE2. During the etching, each silicon oxide film 5 over the gate electrodes GE1 and GE2 is also be removed. Further, the silicon oxide film over the surface of the silicon region 11 is also removed. Incidentally, the silicon oxide film 7 may be entirely removed using wet etching. However, the silicon oxide film 7 is left at each sidewall of the gate electrodes GE1 and GE2. This can protect the gate electrodes GE1 and GE2 during ion implantation described later. Incidentally, the removing step of the silicon oxide film 7 may be omitted to perform ion implantation described later through the silicon oxide film 7.

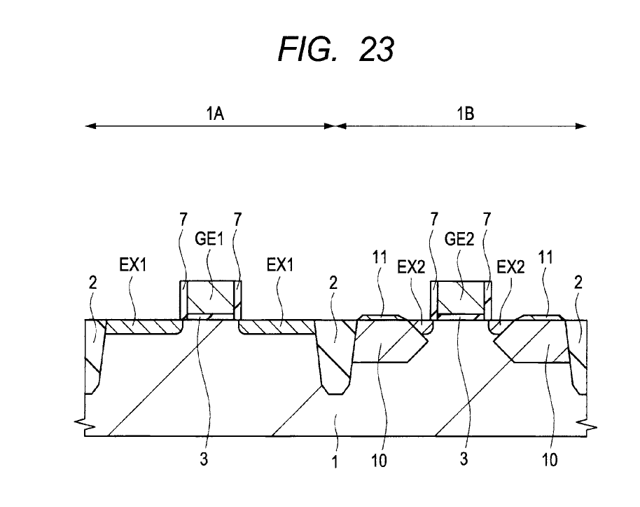

Then, as shown in FIG. 23, in each portion of the silicon substrate 1 on the opposite sides of the gate electrode GE1 in the nMIS region 1A, an n⁻ type semiconductor region (n⁻ type extension region) EX1 is formed. Whereas, in each portion of the silicon substrate 1 on the opposite sides of the gate electrode GE2 in the pMIS region 1B, a p⁻ type semiconductor region (p⁻ type extension region) EX2 is formed.

The n⁻ type semiconductor region EX1 is formed by, for example, ion implanting n type impurities (e.g., phosphorus or arsenic) into the nMIS region 1A with the gate electrode GE1 as a mask. By the step, the n⁻ type semiconductor region EX1 is formed in alignment with the gate electrode GE1. Whereas, the p⁻ type semiconductor region EX2 is formed by, for example, ion implanting p type impurities (e.g., boron) into the pMIS region 1B with the gate electrode GE2 as a mask. By the step, the p⁻ type semiconductor region EX2 is formed in alignment with the gate electrode GE2.

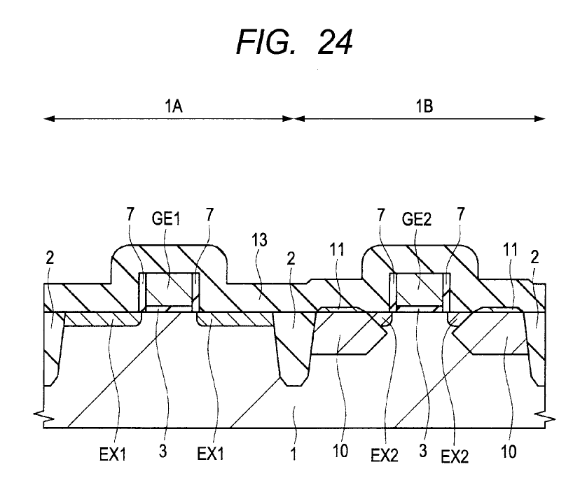

Then, as shown in FIG. 24, over the main surface of the silicon substrate 1, as an insulation film, for example, a silicon nitride film 13 is deposited with a film thickness of about 10 to 40 nm by a CVD method. By the step, the gate electrodes GE1 and GE2 are covered with the silicon nitride film 13.

Then, the silicon nitride film 13 is anisotropically etched (etched back). As a result, at each sidewall of the gate electrodes GE1 and GE2, there is formed a sidewall (sidewall insulation film, sidewall spacer) SW2 including the silicon nitride film 13 (FIG. 25). The anisotropic etching (etching back) removes portions of the silicon nitride film 13 except for the portion left as the sidewall SW2 at each sidewall of the gate electrodes GE1 and GE2. Further, also when the silicon nitride film 6 is left over the gate electrodes GE1 and GE2, the silicon nitride film 6 is removed by the anisotropic etching step for forming the sidewall SW2.

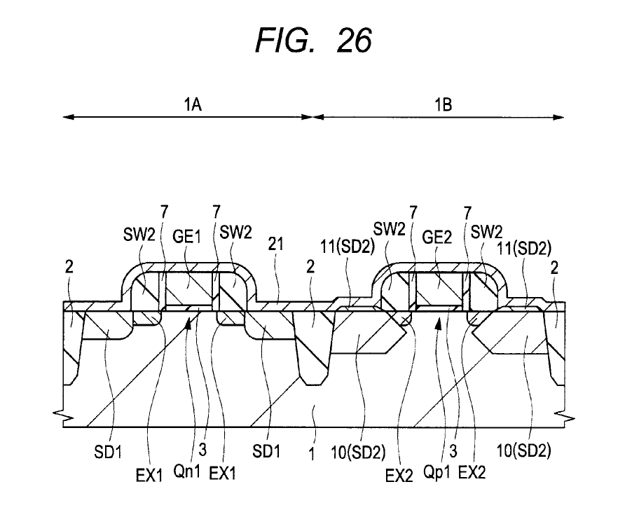

Then, as shown in FIG. 26, in each portion of the silicon substrate 1 on the opposite sides of the gate electrode GE1 and the sidewall SW2, an n⁺ type semiconductor region SD1 is formed. The n⁺ type semiconductor region SD1 is formed by ion implanting n type impurities (e.g., phosphorus or arsenic) into the nMIS region 1A. As the conditions for ion implantation, phosphorus is implanted, for example, at an energy of 5 to 20 keV, and with a concentration of 1E14 to 1E15 cm-2. Incidentally, 1E14 represents 10¹⁴. At this step, the gate electrode GE1 and the sidewall SW2 at the sidewall thereof function as an ion implantation inhibiting mask. For this reason, the n⁺ type semiconductor region SD1 is formed in alignment with the gate electrode GE1 and the sidewall SW2.

Incidentally, as described above, when as the silicon germanium region 10, the non-doped silicon germanium region 10 is deposited, a p⁺ type semiconductor region is formed in the silicon germanium region 10 and the overlying silicon region 11. The p⁺ type semiconductor region is formed by ion implanting p type impurities (e.g., boron) into the pMIS region 1B. As the conditions for ion implantation, for example, at an energy of 0.5 to 2 keV, and with a concentration of 1E15 to 1E16 cm-2, boron is implanted. At this step, the gate electrode GE2 and the sidewall SW2 over the sidewall function as an ion implantation inhibiting mask. For this reason, the p⁺ type semiconductor region is formed in alignment with the gate electrode GE2 and the sidewall SW2.

Further, as described above, when as the silicon germanium region 10, while introducing p type impurities, the silicon germanium region 10 is formed, the region (10) becomes a p⁺ type semiconductor region SD2. Alternatively, when into the silicon germanium region 10 and the overlying silicon region 11, p type impurities (e.g., boron) are implanted, in the silicon germanium region 10, there occurs the boundary between the p⁺ type semiconductor region SD2 and the underlying non-doped region.

After the ion implantation, an annealing treatment for activating the introduced impurities (activation annealing, heat treatment) is performed. For example, about 900 to 1100° C. spike annealing is performed. This can activate the impurities in the n⁻ type semiconductor region EX1, the p⁻ type semiconductor region EX2, the n⁺ type semiconductor region SD1, and the silicon germanium region 10 (p⁺ type semiconductor region SD2).

By the steps up to this point, source/drain regions of a LDD (Lightly doped Drain) structure is formed. Namely, the n⁺ type semiconductor region SD1 and the n⁻ type semiconductor region EX1 are n type semiconductor regions (impurities-diffused layers) functioning as the source or drain of the n channel type MISFET Qn1. The n⁺ type semiconductor region SD1 is formed with a higher impurity concentration and a larger junction depth than those of the n⁻ type semiconductor region EX1. Whereas, the silicon germanium region 10 (p⁺ type semiconductor region SD2) and the p⁻ type semiconductor region EX2 are p type semiconductor regions (impurities-diffused layers) functioning as the source or drain of the p channel type MISFET Qp1. The silicon germanium region 10 (p⁺ type semiconductor region SD2) is formed with a higher impurity concentration and a larger junction depth than those of the p⁻ type semiconductor region EX2.

Further, in the steps, after removal of the sidewall SW1, the sidewall SW2 was newly formed. However, the formation step of the sidewall SW2 can be omitted. For example, the following procedure may be adopted: before the formation step of the sidewall SW1, the n⁻ type semiconductor region EX1 and the p⁻ type semiconductor region EX2 are formed; and after the formation step of the sidewall SW1, the n⁺ type semiconductor region SD1 is formed. Alternatively, when the non-doped silicon germanium region 10 is formed, after the formation step of the sidewall SW1, the silicon germanium region 10 is formed, and further, the p⁺ type semiconductor region SD2 is formed.

By the steps up to this point, in the nMIS region 1A, the n channel type MISFET Qn1 is formed. Whereas, in the pMIS region 1B, the p channel type MISFET Qp1 is formed.

Then, using RCA washing or the like, the surface of the silicon substrate 1 is cleaned. The RCA washing represents a series of washing steps in which hydrofluoric acid washing, ammonia/hydrogen peroxide mixed solution washing, and hydrochloric acid/hydrogen peroxide mixed solution washing are successively performed, and then, washing is performed with ultrapure water. Further, after RCA washing, using hydrofluoric acid or the like, the natural oxide film over the surface of the silicon substrate 1 is removed. The removal step of the natural oxide film exposes the surfaces of the gate electrodes GE1 and GE2, the n⁺ type semiconductor region SD1, and the silicon region 11.

Then, by the Salicide: Self Aligned Silicide technology, over the surfaces of the gate electrodes GE1 and GE2 and the source/drain regions (the n⁺ type semiconductor regions SD1 and the silicon regions 11), metal silicide layers (23a, 23) are formed. Below, the formation step of the metal silicide layers (23a, 23) will be described.

First, as shown in FIG. 26, over the main surface of the silicon substrate 1 including over the gate electrodes GE1 and GE2, the n⁺ type semiconductor regions SD1, and the silicon regions 11, as a metal film, for example, a nickel alloy film 21 is deposited with a film thickness of about 7 to 30 nm using a sputtering method. The nickel alloy film 21 contains at least one or more elements selected from the group consisting of, other than nickel (Ni), Pt (platinum), Pd (palladium), Hf (hafnium), V (vanadium), Al (aluminum), Er (erbium), Yb (ytterbium), and Co (cobalt). As the nickel alloy film 21, an alloy film (NiPtx) containing nickel (Ni) and platinum (Pt) is preferably used. In this case, the composition ratio of Pt is, for example, about 3 to 7 at %.

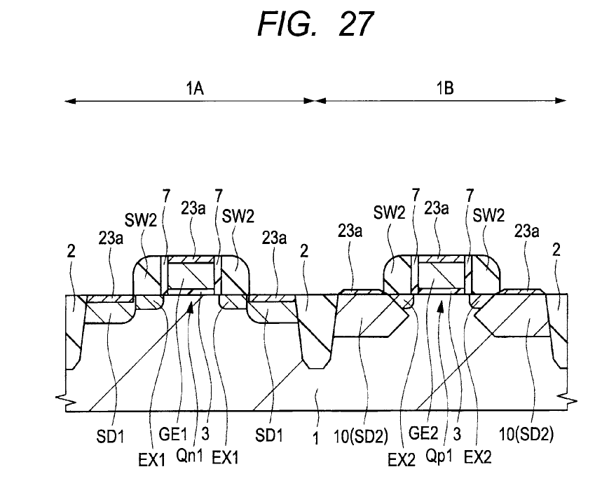

Then, the silicon substrate 1 is subjected to a first heat treatment (annealing treatment). By the first heat treatment, the silicon film (4) forming the gate electrodes GE1 and GE2 and the nickel alloy film 21 are allowed to react with each other. Further, monocrystalline silicon forming the n⁺ type semiconductor region SD1 and the silicon region 11 and the nickel alloy film 21 are allowed to react with each other. As a result, as shown in FIG. 27, there is formed the metal silicide layer 23a which is the reaction layer between the metal and the semiconductor. The first heat treatment is preferably low-temperature short-time annealing. Specifically, as the first heat treatment, a 10- to 120-second heat treatment is performed in a nitrogen (N₂) gas atmosphere at a temperature within the range of 200 to 300° C. Incidentally, the heat treatment may be performed in a mixed gas atmosphere in which a nitrogen gas is mixed with another inert gas (e.g., argon (Ar) gas, neon (Ne) gas, or helium (He) gas). At the stage of having performed the first heat treatment, the metal silicide layer 23a is a metal-rich silicide layer. Namely, the metal silicide layer 23a is a (Ni_{1-y}Me_{y})₂Si phase (0<y<1, z>1). Me represents a metallic element other than Ni contained in the nickel alloy film 21.

Then, by wet etching using, for example, sulfuric acid/hydrogen peroxide mixture or the like, the unreacted portions of the nickel alloy film 21 are removed. The etching treatment time is, for example, about 30 to 60 minutes. As a result, as shown in FIG. 27, the metal silicide layer 23a is left only over the surfaces of the gate electrodes GE1 and GE2, the n⁺ type semiconductor regions SD1, and the silicon regions 11.

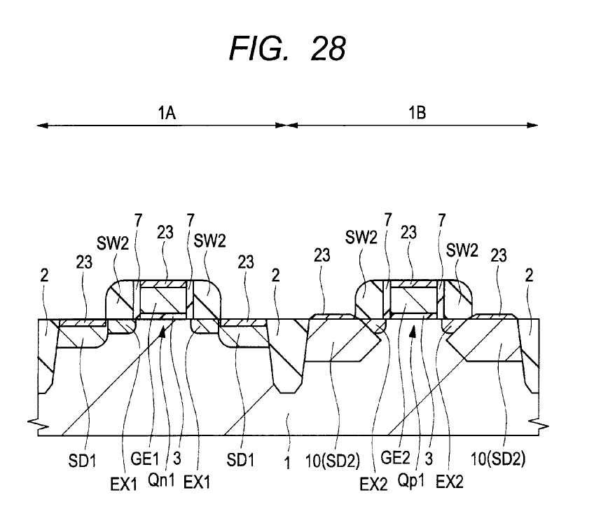

Then, the silicon substrate 1 is subjected to a second heat treatment (annealing treatment). By performing the second heat treatment, the silicidation reaction further proceeds. As shown in FIG. 28, the metal silicide layer 23a becomes a stable metal silicide (Ni_{1-y}Me_{y}Si) layer 23 of which the composition ratio of metallic elements (sum of those of Ni and Me) and Si is close to the stoichiometric ratio of 1:1. The heat treatment temperature of the second heat treatment is required to be set higher than at least the heat treatment temperature of the first heat treatment. Specifically, as the second heat treatment, a 30-second or less heat treatment is performed in a nitrogen (N₂) gas atmosphere at a temperature within the range of 400 to 600° C. Incidentally, the heat treatment may be performed in a mixed gas atmosphere in which a nitrogen gas is mixed with another inert gas (e.g., argon (Ar) gas, neon (Ne) gas, or helium (He) gas).

Incidentally, for the metal silicide layer 23 formed over the source/drain regions (i.e., the p⁺ type semiconductor regions SD2) of the p channel type MISFET Qp1, the underlying silicon germanium region 10 also contributes to the silicidation reaction. Thus, the metal silicide layer 23 may contain Ge therein. Alternatively, only the surface layer part of the silicon region 11 contributes to the silicidation reaction. Thus, a thin silicon region 11 may be left between the silicon germanium region 10 and the metal silicide layer 23. The metal silicide layer 23 can reduce the coupling resistance with a plug PG described later. Incidentally, in the foregoing procedure, silicidation was performed by two-step heat treatments. However, for example, the first heat treatment is performed at a temperature of about 450° C. Thus, the second heat treatment may be omitted.

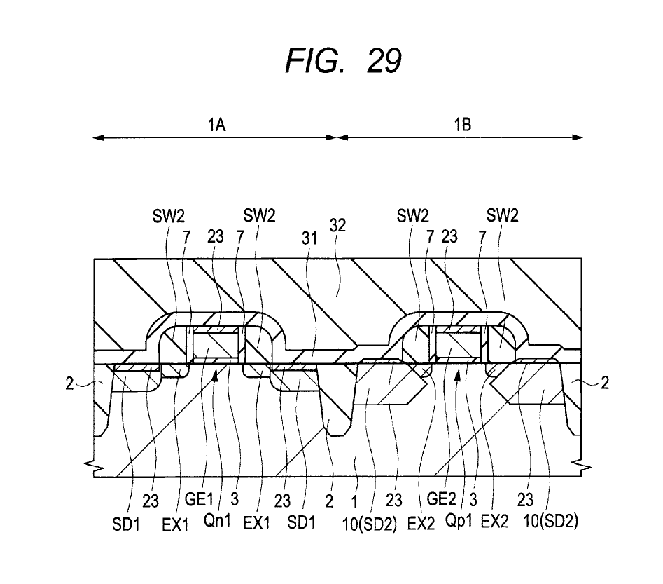

Then, as shown in FIG. 29, over the entire main surface of the silicon substrate 1, as the compressive stress film 31, for example, a silicon nitride film is formed with a film thickness of about 20 to 50 nm using a plasma CVD method or the like. Incidentally, herein, in order to improve the characteristics of the p channel type MISFET Qp1, the compressive stress film 31 was formed. However, in place of the compressive stress film 31, a tensile stress film may be formed. In this case, the characteristics of the n channel type MISFET Qn1 can be improved.

Namely, when the tensile stress film is formed, the mobility of electrons in the channel region of the n channel type MISFET Qn1 can be increased by the tensile stress. This can increase the on current of the n channel type MISFET Qn1. Further, when the compressive stress film is formed, the compressive stress can increase the mobility of holes in the channel region of the p channel type MISFET Qp1. This can increase the on current of the p channel type MISFET Qp1.

When the tensile stress film including the silicon nitride film is formed, for example, using monosilane (SiH₄), dinitrogen monoxide (N₂O), and ammonia (NH₃), a silicon nitride film is deposited at a temperature of about 250° C. to 400° C. by plasma CVD. Then, while applying an ultraviolet ray, an about 400° C. to 550° C. heat treatment is performed. Alternatively, when the compressive stress film including a silicon nitride film is formed, for example, using silane (SiH₄), dinitrogen monoxide (N₂O), and ammonia (NH₃), a silicon nitride film is deposited at a temperature of about 350° C. to 500° C. by plasma CVD.

Herein, a silicon nitride film having a compressive stress of about 1 to 2 GPa is formed as the compressive stress film 31. 1 Pa=1 N/m². Herein, in the present embodiment, as described above, the flatness of the surfaces of the silicon germanium region 10 and the overlying silicon region 11 is improved. For this reason, the compressive stress due to the compressive stress film 31 tends to be applied thereto. This can further improve the characteristics of the p channel type MISFET.

Then, over the compressive stress film 31, as an interlayer insulation film 32, for example, silicon oxide is deposited by a CVD method or the like. Then, the surface of the interlayer insulation film 32 is planarized using a CMP (Chemical Mechanical Polishing) method, or the like.

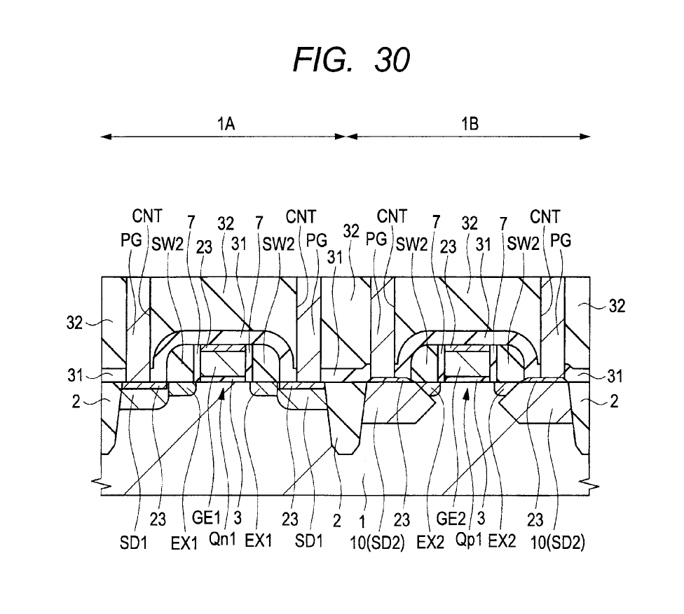

Then, as shown in FIG. 30, the interlayer insulation film 32 and the compressive stress film 31 over the source/drain regions (n⁺ type semiconductor regions SD1) of the n channel type MISFET Qn1 and the source/drain regions (the silicon germanium regions 10 (p⁺ type semiconductor regions SD2)) of the p channel type MISFET Qp1 are selectively removed. As a result, contact holes (through holes, holes) CNT are formed. For example, with the compressive stress film 31 as an etching stopper film, the interlayer insulation film 32 is patterned. Then, the compressive stress film 31 is etched. As a result, the contact holes CNT are formed.

Then, in each contact hole CNT, a conductive film is formed, thereby to form a plug (conductor part for coupling) PG is formed. In order to form the plug PG, for example, over the interlayer insulation film 32 including the inside of the contact hole CNT (over the bottom and the sidewall), a barrier conductor film (not shown) is deposited. Then, over the barrier conductor film, a main conductor film is deposited with a film thickness enough to fill the contact hole CNT. Then, unnecessary portions of the main conductor film and the barrier conductor film over the interlayer insulation film 32 are removed by a CMP method, an etching back method, or the like. As the barrier conductor film, there can be used, for example, a titanium film, a titanium nitride film, or a lamination film thereof. As the main conductor film, a tungsten film or the like can be used.

The plugs PG formed over the source/drain regions (n⁺ type semiconductor regions SD1) of the n channel type MISFET Qn1 come in contact with, and are electrically coupled with the metal silicide layers 23 over the surfaces of the source/drain regions. Whereas, the plugs formed over the source/drain regions (p⁺ type semiconductor regions SD2) of the p channel type MISFET Qp1 come in contact with, and are electrically coupled with the metal silicide layers 23 over the surfaces of the source/drain regions. Further, although not shown, the plugs PG may be formed over the gate electrodes GE1 and GE2.

Then, as shown in FIG. 31, over the interlayer insulation film 32 including over the plugs PG, there are sequentially formed a stopper insulation film 33 and an interlayer insulation film 34. The stopper insulation film 33 has an etching selectivity with respect to the interlayer insulation film 34. For example, as the stopper insulation film 33, a silicon nitride film can be used, and as the interlayer insulation film 34, a silicon oxide film can be used.

Then, by a single damascene method, a first-layer wire M1 is formed. The interlayer insulation film 34 is patterned. Then, the stopper insulation film 33 is etched. As a result, wiring trenches are formed. Then, over the interlayer insulation film 34 including the insides of the wiring trenches, a barrier conductor film (not shown) and a seed layer (not shown) are formed. Then, using an electrolytic plating method or the like, over the seed layer, a metal plating film is formed. Then, portions of the metal plating film, the seed layer, and the barrier metal film in regions other than the wiring trenches are removed by a CMP method. As a result, the first-layer wire M1 is formed. As the barrier conductor film, there can be used, for example, a titanium nitride film, a tantalum film, or a tantalum nitride film. As the seed layer, the seed layer of copper (Cu) can be used. As the metal plating film, a copper plating film can be used.

The wire M1 is electrically coupled through the plugs PG with the source/drain regions (SD1 and SD2), and the gate electrodes GE1 and GE2 of the n channel type MISFET Qn1 and the p channel type MISFET Qp1, and the like. Then, by a dual damascene method or the like. the second- or more-layer wires are formed. However, herein, a description thereon is omitted. Further, the wire M1, and the second- or more-layer wires are not limited to the damascene wires, and can also be formed by patterning a conductor film for wiring. As the conductor film for wiring, for example, tungsten, aluminum (Al), or the like can be used.

Then, over the uppermost-layer wire, a protective film and the like are formed. Then, the silicon substrate 1 is cut (divided) by dicing or the like. As a result, a plurality of semiconductor devices (semiconductor chips) are formed.

FIG. 32 is a plan view showing a configuration example of the semiconductor chip using the semiconductor device of the present embodiment. Thus, the semiconductor device formed by the steps may be used as a semiconductor chip having a memory and peripheral circuits. A semiconductor chip SM1 shown in FIG. 32 has a memory region (memory circuit region, memory cell array region, or SRAM region) 41 in which a memory cell array such as a SRAM (Static Random Access Memory) is formed, and peripheral circuit regions 42 in which circuits (peripheral circuits) other than the memory are formed. The peripheral circuit regions 42 include a logic circuit 42a in which a logic circuit is formed. An electric coupling is established, if necessary, between the memory region 41 and the peripheral circuit region 42, and between the peripheral circuit regions 42 via the internal wiring layers (the wire M1 and higher-layer wires) of the semiconductor chip SM1. Further, at the peripheral part of the main surface (front surface) of the semiconductor chip SM1, a plurality of pad electrodes (bonding pads) PD are formed along the four sides of the main surface of the semiconductor chip SM1. Respective pad electrodes PD are electrically coupled via the internal wiring layers of the semiconductor chip SM1 with the memory region 41, the peripheral circuit regions 42, and the like. Incidentally, FIG. 32 is a plan view. However, for ease of understanding, the memory region 41 and the logic circuit regions 42a are hatched.

For example, the SRAM memory cell may be configured using the p channel type MISFET Qp1 and the n channel type field effect transistor Qn1. Alternatively, the logic circuit in the logic circuit region 42a may be configured using the p channel type MISFET Qp1 and the n channel type field effect transistor Qn1.

For example, for the density of the elements, elements are formed densely in the memory region 41. Alternatively, in the logic circuit region 42a, a dense portion and a sparse portion of the elements may occur according to the layout of the logic circuit. Even with a variation in density of the elements, in accordance with the present embodiment, it is possible to reduce the variation in rising amount H of the silicon germanium region 10 (see FIG. 21).

As described in details up to this point, in accordance with the present embodiment, it is possible to improve the characteristics of the semiconductor device.

FIG. 33 is a cross-sectional photograph of the semiconductor device (p channel type MISFET Qp1) prototyped by the present inventors. FIG. 34 is a reproduced diagram of the photograph. As shown in FIGS. 33 and 34, at the boundary between the silicon substrate 1 and the silicon germanium region 10, there can be observed a (100) plane which is the first inclined surface, and a (100) plane crossing the (100) plane at an angle of 90° which is the second inclined surface. Further, it can be observed that the top surface of the silicon germanium region 10 is formed at a position lower than the top surface of the gate insulation film 3. Further, as described above, in the semiconductor device of the present embodiment, about 20% improvement in mobility than Comparative Example can be observed (FIG. 17).

Incidentally, the step is one example. It is naturally understood that various modifications may be made. For example, in the nMIS region 1A or in the pMIS region 1B, a well may be formed. Alternatively, the following procedure may be adopted: into the metal silicide layer 23 in the nMIS region 1A, Al (aluminum) is injected to cause a tensile stress; this improves the characteristics of the n channel type MISFET Qn1. Still alternatively, with the top of the nickel alloy film 21 protected by a barrier film, silicidation may be performed. Further, in the present embodiment, the silicon substrate 1 was used. However, other semiconductor substrates may be used so long as the trench g2 can be formed therein. Further, for the silicon germanium region 10, and a silicon carbide region 12, there may be used other semiconductor materials different in lattice constant from the semiconductor materials forming the substrate.

### Second Embodiment

In the first embodiment, by two-stage etching by first etching and second etching, the trench g2 in the desired shape was formed. However, in the present embodiment, after first etching, ion implantation is performed, and then second etching is performed.

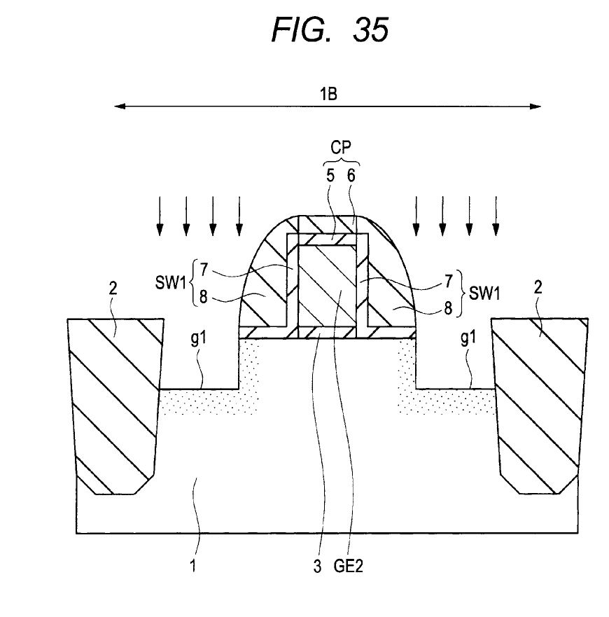

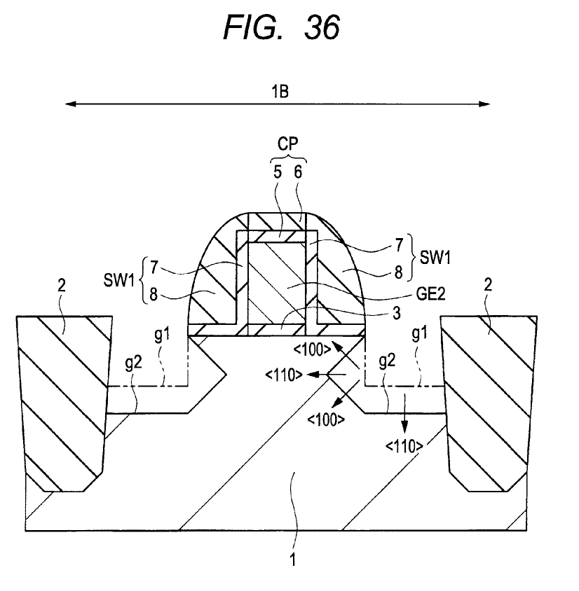

FIGS. 35 and 36 are each a cross-sectional view showing a manufacturing step of a semiconductor device of the present embodiment.

First, as with the first embodiment, a silicon substrate 1 with a plane orientation of (110) is prepared. The element isolation region 2, the gate insulation film 3, the gate electrodes GE1 and GE2, the sidewall SW1, and the cap insulation film CP are formed (see FIGS. 7 and 8).

Then, with the sidewall SW1 and the cap insulation film CP in the shapes as a mask, first etching is performed. Specifically, in the pMIS region 1B, each portion of the silicon substrate 1 on the opposite sides of the gate electrode (sidewall SW1) GE2 is etched from the surface to a prescribed depth, thereby to form a trench g1. The first etching is performed by anisotropic dry etching, so that the trench shape is made a general box shape. For example, the depth of the trench is set at about 30 nm to 50 nm. By the first etching, on the gate electrode GE2 side of the trench g1, the first side surface is exposed. On the element isolation region 2 side, the second side surface is exposed. Herein, as the second side surface, the sidewall of the element isolation region 2 is exposed. The surface of the silicon substrate 1 is, as described above, the (110) plane. Accordingly, at the first side surface of the trench g1 on the gate electrode GE2 side, the (110) plane of the silicon substrate 1 is exposed, and at the bottom surface, the (110) plane of the silicon substrate 1 is exposed (see FIG. 10).

Then, as shown in FIG. 35, in the pMIS region 1B, with the sidewall SW1 and the cap insulation film CP as a mask, the silicon substrate 1 is subjected to ion implantation of Ge ions. As a result, into the bottom surface and the first side surface which is the side surface on the gate electrode GE2 side of the trench g1, Ge ions are implanted. Thus, a damage layer is formed. In order to form the damage layer with a large thickness at the first side surface part, oblique ion implantation may be performed.

Then, as shown in FIG. 36, second etching is performed. As a result, the silicon substrate 1 exposed from the first sidewall and the bottom surface of the trench g1 is further retreated, thereby to form the trench g2. The second etching is performed by the same anisotropic wet etching as that in the first embodiment. The step forms the trench g2 having a (100) plane, and a (100) plane crossing the (100) plane at an angle of 90°.

Then, as with the first embodiment, in the trench g2 in the pMIS region 1B, the p type silicon germanium (SiGe) is epitaxially grown, so that the silicon germanium region 10 (SD2) is formed. Further, continuously, over the silicon germanium region 10, silicon (Si) is epitaxially grown, thereby to form the silicon region 11.

Then, as with the first embodiment, the silicon nitride film 8 in the nMIS region 1A, the silicon nitride film 8 of the sidewall SW1 in the pMIS region 1B, and the silicon nitride film 6 over the gate electrodes GE1 and GE2 are removed. Thus, the n⁻ type semiconductor region EX1 and the p⁻ type semiconductor region EX2 are formed (see FIG. 23). Further, the sidewall SW2 is formed, and then, the n⁺ type semiconductor region SD1 is formed (see FIG. 25). The subsequent steps are the same as those of the first embodiment, and hence a description thereon will be omitted.

Thus, the present embodiment produces, in addition to the effects described in the first embodiment, the following effects. Namely, the damage layer by ion implantation of Ge ions was formed, and hence wet etching tends to proceed. Thus, a (100) plane, and a (100) plane crossing the (100) plane at an angle of 90° are exposed at an early stage. Further, the areas of the planes exposed also increase. Further, the crystallinity of the silicon germanium region 10 formed inside the trench g2 is also improved, which can further improve the characteristics of the p channel type MISFET Qp1.

Incidentally, in the ion implantation for forming the damage layer, other than the Ge ions, Si ions may be implanted.

### Third Embodiment

In the first embodiment, the silicon germanium region 10 includes 60 to 80 at % Si and 20 to 40 at % Ge. However, in the present embodiment, the Ge concentration of the silicon germanium region 10 is set at 25 at % or more. Incidentally, the configurations and the manufacturing steps in the present embodiment are the same as those in the first embodiment, except for the configuration (composition ratio) and the manufacturing method of the silicon germanium region 10. Therefore, a description on the configurations and the manufacturing steps other than those of the silicon germanium region 10 will be omitted.

As described above, the silicon germanium region 10 can be formed by epitaxial growth using, for example, a silane series gas and a germane series gas as raw material gases. As the silane series gases, there can be used, for example, monosilane gas (SiH₄) and dichlorosilane (SiH₂Cl₂). Whereas, as the germane series gases, monogermane gas (GeH₄) and the like can be used. Further, by adjusting the ratio of the supply amount (flow rate) of the germane series gas to the supply amount of the silane series gas, it is possible to change the concentration (ratio, composition ratio) of Ge in the silicon germanium region 10. Accordingly, during the epitaxial growth, the ratio of the supply amount (flow rate) of the germane series gas to the supply amount of the silane series gas is set higher. This can increase the Ge concentration in the silicon germanium region 10.

Incidentally, as with the first embodiment, the silicon germanium region 10 can be formed with a thickness of, for example, about 40 to 100 nm. The silicon region 11 can be formed with a thickness of, for example, about 5 to 20 nm. Herein, deposition is performed with p type doping gas (gas for adding p type impurities) such as boron hydride (B₂H₆) contained in the raw material gases. As a result, the p type silicon germanium region 10 is formed. Incidentally, after deposition of a non-doped silicon germanium region 10, p type impurity ions may be implanted by an ion implantation method.

There will be shown one example of the epitaxial growth conditions of the silicon germanium region 10 in the present embodiment. For the formation of the silicon germanium region 10, for example, in a reaction chamber (chamber), under a 650° C. and 1.33 kPa atmosphere, as the raw material gases, dichlorosilane, monogermane gas, and boron hydride (B₂H₆) are introduced at flow rates of 20 sccm, 16 sccm, and 160 sccm, respectively, together with hydrochloric acid (HCl) at a flow rate of 35 ccm which is a carrier gas. When silicon germanium is epitaxially grown under such conditions, the amount of Ge in terms of atomic percent is about 30%, and the amount of Si in terms of atomic percent is about 70%. Namely, when silicon germanium is expressed as Si₁₋ₓGeₓ, x≈0.3.

Thereafter, as with the first embodiment, continuously silicon (Si) is epitaxially grown over the silicon germanium region 10, thereby to form the silicon region 11.

Thus, an increase in Ge concentration in the silicon germanium region 10 results in an increase in number of sites each having a large lattice constant. This results in an increase in compressive stress to the channel region of the p channel type MISFET Qp1. As a result, it is possible to further improve the characteristics of the p channel type MISFET Qp1. The Ge concentration in the silicon germanium region 10 is desirably set at 25 at % or more.

### Fourth Embodiment

In the present embodiment, in epitaxial growth of the silicon germanium, the ratio of the supply amount (flow rate) of the germane series gas to the supply amount of the silane series gas is changed during growth thereof. Incidentally, the configurations and the manufacturing steps in the present embodiment are the same as those in the first embodiment, except for the configuration (composition ratio) and the manufacturing method of the silicon germanium region 10. Therefore, a description on the configurations and the manufacturing steps other than those of the silicon germanium region 10 will be omitted.

As described above, the silicon germanium region 10 can be formed by epitaxial growth using, for example, a silane series gas and a germane series gas as raw material gases. As the silane series gases, there can be used, for example, monosilane gas (SiH₄) and dichlorosilane (SiH₂Cl₂). Whereas, as the germane series gases, monogermane gas (GeH₄) and the like can be used. Further, by adjusting the ratio of the supply amount (flow rate) of the germane series gas to the supply amount of the silane series gas, it is possible to change the concentration (ratio, composition ratio) of Ge in the silicon germanium region 10. Accordingly, during the epitaxial growth, the ratio of the supply amount (flow rate) of the germane series gas to the supply amount of the silane series gas is changed. This can change the Ge concentration in the silicon germanium region 10. For example, at the early stage of growth, growth is effected only with a silane series gas (Si₁₋ₓGeₓ where x is 0), and gradually the ratio of the supply amount of the germane series gas to the supply amount of the silane series gas is increased. At the latter stage of growth, the flow rate ratio of the supply amount of the silane series gas and the supply amount of the germane series gas is adjusted so that x of Si₁₋ₓGeₓ is about 0.4. In this case, x in the silicon germanium region 10 (Si₁₋ₓGeₓ) increases from 0 to 0.4.

Herein, as described above, in epitaxial growth of the silicon germanium region 10, crystal growth preferentially proceeds from a (100) plane, and a (100) plane crossing the (100) plane at an angle of 90° to be the side surface of the trench g2. Accordingly, at the side surface (the first inclined surface and the second inclined surface, or the sidewall part) of the trench g2, the germanium concentration is lower than the germanium concentrations of other regions. The germanium concentration increases in the growth direction.

For example, the Ge concentration increases with the progress of growth from the side surface (the first inclined surface and the second inclined surface, or the sidewall part) of the trench g2 in the direction of the inside of the trench g2, and further in the second side surface direction (the direction of the element isolation region 2) of the trench g2. Further, the Ge concentration increases from the bottom surface toward the top surface of the trench g2. However, as described above, crystal growth is more likely to occur at the (100) plane forming the first side surface than at the (110) plane forming the bottom surface of the trench g2. For this reason, the concentration gradient in the transverse direction (from the first side surface toward the second side surface) is larger. Incidentally, as the second side surface of the trench g2, not the element isolation region 2 but the silicon substrate 1 may be exposed. In this case, crystal growth also proceeds from the second side surface in the direction of the inside of the trench g2.

Accordingly, in the side surface (the first inclined surface and the second inclined surface, or the sidewall part) of the trench g2, as described above, the germanium concentration is lower than the germanium concentration of other regions. More particularly, it can be said that at least the silicon germanium region 10 at the side surface (the first inclined surface and the second inclined surface, or the sidewall part) of the trench g2 is lower in concentration than the silicon germanium region 10 in the surface at the intermediate part between the first side surface (on the gate electrode GE2 side) and the second side surface (on the element isolation region 2 side) of the trench g2.

Thus, while gradually increasing the ratio of the supply amount of the germane series gas, epitaxial growth of silicon germanium is performed. As a result, crystal strain in the vicinity of the first sidewall and the bottom surface part of the trench g2 is reduced. This can reduce the crystal defects, and can improve the deposition property. On the other hand, in the silicon germanium region 10, the Ge concentration gradually increases from the vicinity of the sidewall part of the trench g2. Accordingly, sites with a large lattice constant increase in number, and finally, the Ge concentration becomes about 40 at %. This increases the strain due to SiGe, which can increase the compressive stress to the channel region of the p channel type MISFET Qp1.

### Fifth Embodiment

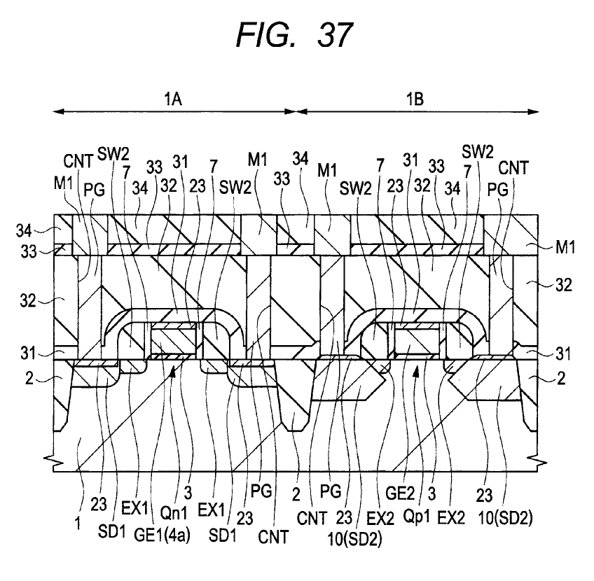

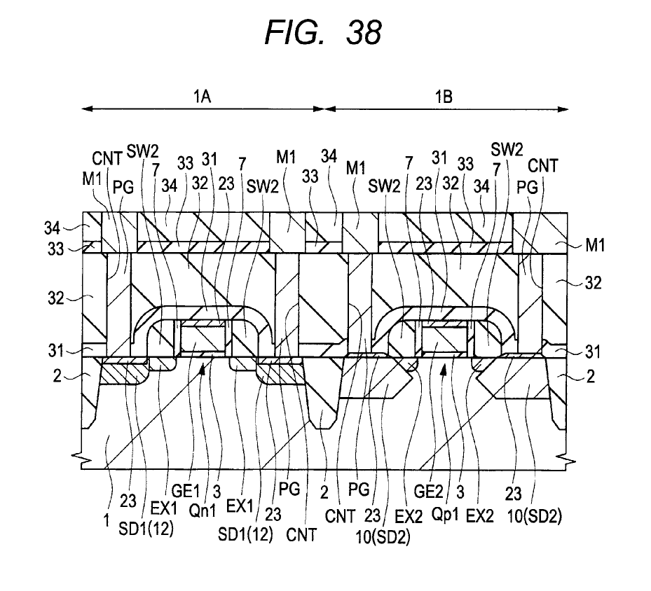

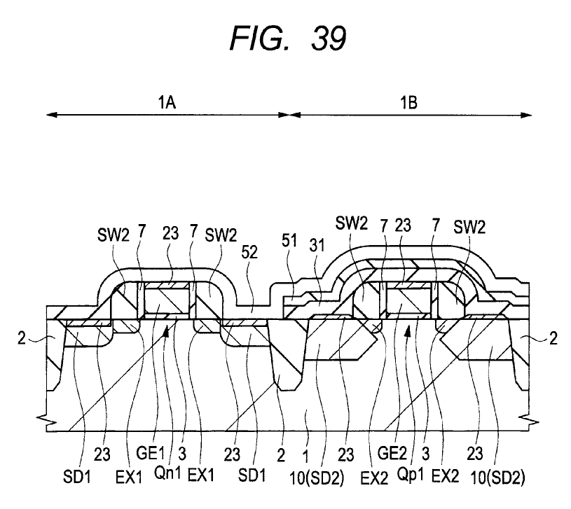

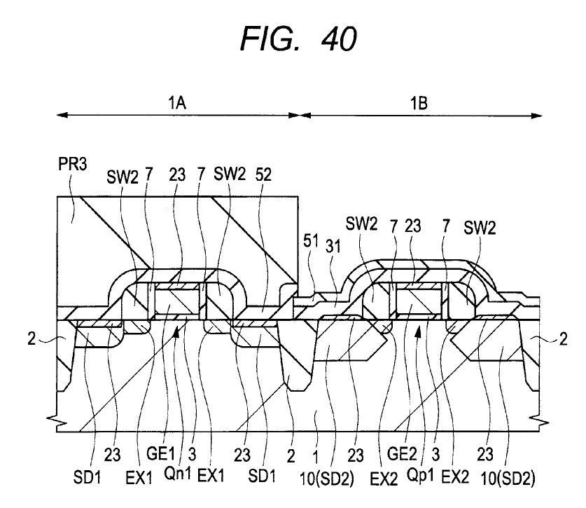

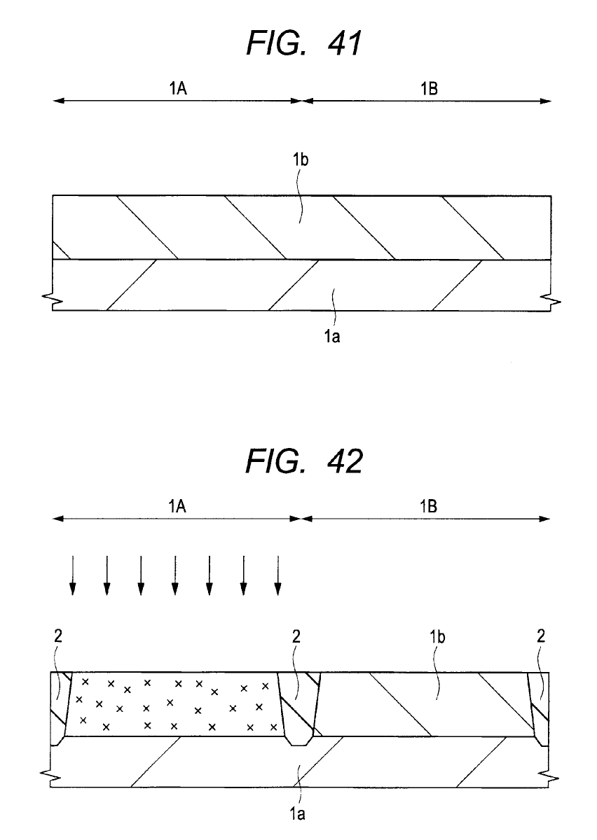

In the first embodiment, in the trench g2 in the desired shape, the silicon germanium region 10 was formed. Further over the p channel type MISFET Qp1, the compressive stress film 31 was formed. As a result, the characteristics of the p channel type MISFET Qp1 were improved. However, in the present embodiment, a description will be given to various applied examples for improving even the characteristics of the n channel type MISFET Qn1. FIGS. 37 to 44 are each an essential part cross-sectional view showing a semiconductor device of the present embodiment and a manufacturing step thereof. FIG. 37 corresponds to Applied Example 1; FIG. 38, to Applied Example 2; FIGS. 39 and 40, to Applied Example 3; and FIGS. 41 to 44, to Applied Example 4. Incidentally, also in the present embodiment, a detailed description will be given to different configurations and manufacturing steps from those of the first embodiment.

### Applied Example 1

In a semiconductor device shown in FIG. 37, as a gate insulation film 3a of the n channel type MISFET Qn1, a high dielectric constant insulation film (high-k insulation film) is used. As a conductive film forming the gate electrode GE1, a lamination conductive film 4a having a metal film and polysilicon (polycrystal silicon film) disposed over the metal film is used. A so-called metal gate electrode (GE1) is used. Other than the lamination conductive film 4a, a metal compound film may be used.

Thus, by using the high dielectric constant insulation film as the gate insulation film 3a, it is possible to increase the current amount of the n channel type MISFET Qn1. Further, it becomes possible to increase the film thickness of the gate insulation film 3a. This can reduce the leakage current. Further, the combination of the gate insulation film (high dielectric constant insulation film) 3a and the metal gate electrode (GE1) suppresses the phonon vibration inhibiting the flow of electrons. This further improves the driving characteristics of the n channel type MISFET Qn1.

As the high dielectric constant insulation film (3a), there can be used, for example, HfO₂, HfSiON, La₂O₃, or Al₂O₃. Further, as the metal film forming the metal gate electrode (GE1), there can be used, for example, Al, Ru, or W. Alternatively, there may be used a conductive compound of a metal and nitrogen, or a conductive compound including a metal, a semiconductor, and nitrogen, such as TiN or TaSiN. Further, as the metal gate electrode (GE1), the metal film or the conductive compound may be used as a monolayer. Further, the metal gate electrode (GE1) may be a lamination film of the conductive compound and polysilicon provided over the conductive compound.

The gate insulation film (high dielectric constant insulation film) 3a and the metal gate electrode (GE1) of the n channel type MISFET Qn1 have no restriction on the formation method, but can be formed by, for example, the following steps.

As with the first embodiment, in the silicon substrate 1, as the element isolation region 2 and the gate insulation film 3, thin silicon oxide films are formed. Then, the silicon oxide film in the nMIS region 1A is removed. Only in the nMIS region 1A, as the gate insulation film 3a, a high dielectric constant insulation film is formed.

Then, as with the first embodiment, over the gate insulation film 3, as conductive films, a silicon film 4, a silicon oxide film 5, and a silicon nitride film 6 are formed. Then, the films are patterned, thereby to form a gate electrode GE2 and a cap insulation film CP in the pMIS region 1B. Then, only over the gate insulation film 3a in the nMIS region 1A, as a lamination conductive film 4a, a metal film and polysilicon provided on the metal film, the silicon oxide film 5, and the silicon nitride film 6 are formed. Then, the films are patterned, resulting in the formation of the metal gate electrode (GE1) including the lamination conductive film 4a and the cap insulation film CP.

Thereafter, as with the first embodiment, at the sidewalls of the gate electrodes GE1 and GE2, the sidewalls SW1 are formed. Then, in the pMIS region, the tow-stage etching step described in details in the first embodiment is performed, thereby to form each trench g2. In the inside of the trench g2, p type silicon germanium is epitaxially grown, thereby to form the p type the silicon germanium region 10 (SD2). Subsequently, continuously, over the silicon germanium region 10, silicon (Si) is epitaxially grown, thereby to form the silicon region 11.

Then, as with the first embodiment, the sidewall SW1 is removed. In the nMIS region 1A, the n⁻ type semiconductor regions EX1 are formed. Whereas, in the pMIS region 1B, the p⁻ type semiconductor regions EX2 are formed. Then, at the sidewalls of the gate electrodes GE1 and GE2, sidewalls SW2 including the silicon nitride film 13 are formed. Then, in portions of the silicon substrate 1 on the opposite sides of the gate electrode GE1 and the sidewall SW2, n⁺ type semiconductor regions SD1 are formed. Then, as with the first embodiment, by the salicide technology, over the surfaces of the gate electrodes GE1 and GE2 and the source/drain regions, the metal silicide layers 23 are formed. Then, over the entire main surface of the silicon substrate 1, a compressive stress film 31 is formed. Then, as with the first embodiment, there are formed the interlayer insulation film 32, plugs PG, the stopper insulation film 33, and the interlayer insulation film 34, and the first-layer wire M1.

Thus, the present embodiment produces, in addition to the effects of the first embodiment, the following effects. Namely, as described in the first embodiment, use of the silicon substrate 1 of (110) can improve the mobility of holes in the p channel type MISFET Qp1. However, when the (110) silicon substrate 1 is used, the mobility of electrons in the n channel type MISFET Qn1 becomes lower as compared with the case where the (100) silicon substrate is used.

However, in Applied Example 1 of the present embodiment, as the gate insulation film 3a of the n channel type MISFET Qn1, the high dielectric constant insulation film was used. As the conductive film forming the gate electrode GE1, the lamination conductive film (a metal film and polysilicon disposed over the metal film) 4a was used. For this reason, as described above, the driving characteristics of the n channel type MISFET Qn1 can be improved.

Thus, in the present embodiment, it is possible to improve the characteristics of both the p channel type MISFET Qp1 and the n channel type MISFET Qn1.

Incidentally, for the gate insulation film 3 of the p channel type MISFET Qp1, a high dielectric constant insulation film (high-k insulation film) may be used. For the gate electrode GE2, a metal gate electrode may be used. For the high dielectric constant insulation film of the gate insulation film 3 of the p channel type MISFET Qp1, the same material as that for the gate insulation film 3a of the n channel type MISFET Qn1 may be used, and the same configuration may be adopted. Whereas, for the gate electrode GE2 of the p channel type MISFET Qp1, the same material as that for the gate electrode GE1 of the n channel type MISFET Qn1 may be used, and the same configuration may be adopted. Alternatively, for the n channel type MISFET Qn1 and the p channel type MISFET Qp1, different high dielectric constant insulation films and gate electrode materials may be used, respectively, in order to optimally control the work functions of the semiconductors under the channels, respectively. Still alternatively, for the n channel type MISFET Qn1 and the p channel type MISFET Qp1, in order to optimally control the work functions of the semiconductor under the channels, different configurations may be adopted for the high dielectric constant insulation films and the gate electrodes, respectively.

Thus, for the gate insulation film 3 of the p channel type MISFET Qp1, the high dielectric constant insulation film (high-k insulation film) is used. For the gate electrode GE2, the metal gate electrode is used. As a result, it is possible to further improve the characteristics of the p channel type MISFET Qp1.

### Applied Example 2

In a semiconductor device shown in FIG. 38, the source/drain regions (n⁺ type semiconductor regions SD1 and SD3) of the n channel type MISFET Qn1 are each disposed in the silicon carbide (SiC) region 12. With such a structure, a tensile stress is allowed to act on (applied to) the channel region of the n channel type MISFET Qn1. This can increase the mobility of electrons (the mobility of electrons in the channel region). As a result, it is possible to increase the on current passing through the channel of the n channel type MISFET Qn1, which can implement a higher speed operation. The silicon carbide region 12 causes a tensile stress to act on the channel region. This is mainly due to the fact that the lattice constant of silicon carbide region 12 is smaller than the lattice constant of silicon (silicon substrate 1).

The silicon carbide region 12 of the n channel type MISFET Qn1 has no restriction on the formation method thereof, but can be formed by, for example, the following steps.

As with the first embodiment, in the silicon substrate 1, the element isolation region 2, the gate insulation film 3, the gate electrodes GE1 and GE2, the cap insulation film CP, and the sidewall SW1 are formed. Then, in the pMIS region, the two-stage etching step described in details in the first embodiment is performed, thereby to form the trench g2. In the inside of the trench g2, p type silicon germanium is epitaxially grown, thereby to form a p type silicon germanium region 10 (SD2). Subsequently, continuously, over the silicon germanium region 10, silicon (Si) is epitaxially grown, thereby to form the silicon region 11 (see FIG. 22). Further, after the formation of the sidewall SW1, in the nMIS region, with the sidewall SW1 as a mask, cluster carbon is injected. Then, each portion of the silicon substrate 1 on the opposite sides of the sidewall SW1 is made amorphous. Then, a heat treatment is performed, so that the region made amorphous is recrystallized. This results in the formation of the silicon carbide region 12 in each portion of the silicon substrate 1 on the opposite sides of the sidewall SW1.

Then, as with the first embodiment, in the nMIS region 1A, each n⁻ type semiconductor region EX1 is formed. Whereas, in the pMIS region 1B, each p⁻ type semiconductor region EX2 is formed. Then, at each sidewall of the gate electrodes GE1 and GE2, the sidewall SW2 including the silicon nitride film 13 is formed. Then, in each portion of the silicon carbide region 12 on the opposite sides of the gate electrode GE1 and the sidewall SW2, the n⁺ type semiconductor region SD1 is formed.

Thereafter, as with the first embodiment, by the salicide technology, over the surfaces of the gate electrodes GE1 and GE2, and the source/drain regions (the n⁺ type semiconductor regions SD1 and the p⁺ type semiconductor regions SD2), the metal silicide layers (23a or 23) are formed. Then, over the entire main surface of the silicon substrate 1, the compressive stress film 31 is formed. Then, as with the first embodiment, there are formed the interlayer insulation film 32, the plugs PG, the stopper insulation film 33, and the interlayer insulation film 34, and the first-layer wire M1.

Thus, the present embodiment produces, in addition to the effects of the first embodiment, the following effects. Namely, as described in the first embodiment, use of the silicon substrate 1 of (110) can improve the mobility of holes in the p channel type MISFET Qp1. However, when the (110) silicon substrate 1 is used, the mobility of electrons in the n channel type MISFET Qn1 becomes lower as compared with the case where the (100) silicon substrate is used.

However, in Applied Example 2 of the present embodiment, the source/drain regions of the n channel type MISFET Qn1 were formed in the silicon carbide region 12. For this reason, as described above, a tensile stress can be allowed to act of the channel region of the n channel type MISFET Qn1. This can improve the driving characteristics of the n channel type MISFET Qn1.

Thus, in the present embodiment, it is possible to improve the characteristics of both the p channel type MISFET Qp1 and the n channel type MISFET Qn1.

### Applied Example 3

In a semiconductor device shown in FIGS. 39 and 40, over the source/drain regions of the n channel type MISFET Qn1, a tensile stress film (tensile liner film) 52 is formed. Over the source/drain regions of the p channel type MISFET Qp1, a compressive stress film 31 is formed. Such a structure may be referred to as a dual stress liner structure.

Thus, the compressive stress film 31 over the nMIS region 1A is removed, and the tensile stress film 52 is formed. This can increase the mobility of electrons in the channel region of the n channel type MISFET Qn1. As a result, it is possible to increase the on current of the n channel type MISFET Qn1.

The tensile stress film 52 over the n channel type MISFET Qn1 has no restriction on the formation method thereof, but can be formed by, for example, the following steps.

As with the first embodiment, in the silicon substrate 1, the element isolation region 2 is formed. Then, in the nMIS region 1A, the n channel type MISFET Qn1 is formed. In the pMIS region 1B, the p channel type MISFET Qp1 is formed. Then, by the salicide technology, over the surfaces of the gate electrodes GE1 and GE2 and the source/drain regions, the metal silicide layers 23 are formed (see FIG. 28). Then, as with the first embodiment, over the entire main surface of the silicon substrate 1, a compressive stress film 31 is formed. Then, as shown in FIG. 39, over the compressive stress film 31, as an etching stopper film, an insulation film 51 is formed. The insulation film 51 is required to be formed of a different material from that for the tensile stress film 52 described later. For example, when the tensile stress film 52 formed later is a silicon nitride film, as the insulation film 51, a silicon oxide film is preferable. However, other than this, a silicon carbide film, a silicon carbonitride film, or a silicon oxynitride film can be used as the insulation film 51. The film thickness (formed film thickness) of the insulation film 51 is, for example, about 6 to 20 nm.

Then, the insulation film 51 and the underlying compressive stress film 31 in the nMIS region 1A are dry etched and removed. Then, over the entire main surface of the silicon substrate 1, a tensile stress film 52 is formed. The tensile stress film 52 includes, for example, silicon nitride, and can be formed by a plasma CVD method or the like. The film thickness (deposited film thickness) can be set at about 20 to 50 nm. When the tensile stress film 52 including silicon nitride is thus formed, for example, using silane (SiH₄), dinitrogen monoxide (N₂O), and ammonia (NH₃), a silicon nitride film is deposited at a temperature of about 250° C. to 400° C. by plasma CVD. Then, while applying an ultraviolet ray, an about 400° C. to 550° C. heat treatment is performed. As a result, a tensile stress film including the silicon nitride film can be formed. The tensile stress of the tensile stress film 52 is, for example, about 1 to 2 GPa. Then, as shown in FIG. 40, the nMIS region 1A is covered with a photoresist film PR3. Thus, the tensile stress film 52 in the pMIS region 1B is dry etched and removed. In the dry etching step, the insulation film 51 is allowed to function as an etching stopper.

Then, the photoresist film PR3 is removed. Then, as with the first embodiment, there are formed the interlayer insulation film 32, the plugs PG, the stopper insulation film 33, and the interlayer insulation film 34, and the first-layer wire M1.

Thus, the present embodiment produces, in addition to the effects of the first embodiment, the following effects. Namely, as described in the first embodiment, use of the silicon substrate 1 of (110) can improve the mobility of holes in the p channel type MISFET Qp1. However, when the (110) silicon substrate 1 is used, the mobility of electrons in the n channel type MISFET Qn1 becomes lower as compared with the case where the (100) silicon substrate is used.

However, in Applied Example 3 of the present embodiment, over the source/drain regions of the n channel type MISFET Qn1, the tensile stress film 52 was disposed. For this reason, as described above, the mobility of electrons is increased, which can increase the on current. This can improve the driving characteristics of the n channel type MISFET Qn1.

Thus, in the present embodiment, it is possible to improve the characteristics of both the p channel type MISFET Qp1 and the n channel type MISFET Qn1.

### Applied Example 4

In a semiconductor device of the present embodiment, there is used a silicon substrate 1a having an nMIS region 1A with a plane orientation of (100), and a pMIS region 1B with a plane orientation of (110). Thus, in the nMIS region 1A with a plane orientation of (100), an n channel type MISFET Qn1 is formed. In the pMIS region 1B with a plane orientation of (110), a p channel type MISFET Qp1 is formed (see FIG. 44). Thus, the n channel type MISFET Qn1 is formed in a region with a plane orientation of (100). As a result, the mobility of electrons in the channel region can be increased, which can increase the on current.

Below, referring to the drawings, a description will be given to a method for manufacturing the semiconductor device of the present embodiment. First, a description will be given to a formation method of the silicon substrate 1a having different plane orientations at the main surface thereof. to the top of the silicon substrate 1a with a plane orientation of (100), a silicon substrate 1b with a plane orientation of (110) is bonded. Thus, the silicon substrate 1b side is polished, thereby to reduce the thickness of the silicon substrate 1b. Below, 1b will be referred to as a silicon layer.

Then, as with the first embodiment, an element isolation region 2 is formed. For example, in the silicon layer 1b over the silicon substrate 1a, an element isolation trench surrounding the nMIS region 1A and the pMIS region 1B is formed. In the inside of the element isolation trench, an insulation film is embedded, thereby to form the element isolation region 2. Incidentally, the depth of the element isolation trench is preferably larger than the thickness of the silicon layer 1b.

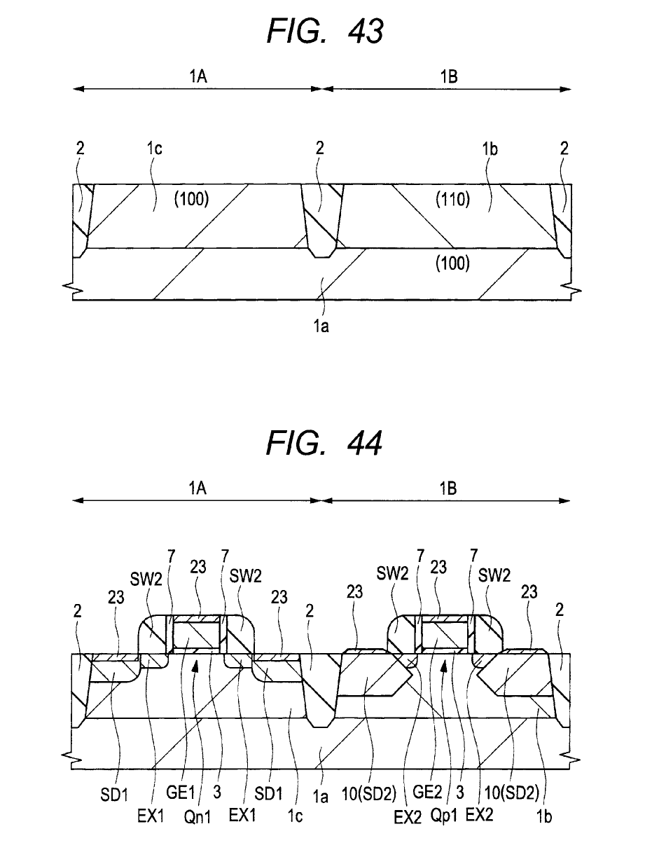

Then, as shown in FIG. 42, silicon ions are implanted into the nMIS region 1A, so that the silicon layer 1b in the nMIS region 1A is made amorphous. Then, a heat treatment is performed, thereby to recrystallize the region made amorphous. At this step, the plane orientation of the underlying silicon substrate 1a is (100), and hence the silicon layer with a plane orientation of (100) is grown (recrystallized). Accordingly, as shown in FIG. 43, the silicon layer 1b in the nMIS region 1A becomes a silicon layer 1c with a plane orientation of (100).

Then, as with the first embodiment, in the nMIS region 1A, the n channel type MISFET Qn1 is formed. In the pMIS region 1B, the p channel type MISFET Qp1 is formed. Further, thereafter, if required, as with the first embodiment, there are formed the metal silicide layer 23, the compressive stress film 31, the interlayer insulation film 32, the plugs PG, the stopper insulation film 33, and the interlayer insulation film 34, the first-layer wire M1, and the like.

Thus, the present embodiment produces, in addition to the effects of the first embodiment, the following effects. Namely, as described in the first embodiment, use of the silicon substrate 1 of (110) can improve the mobility of holes in the p channel type MISFET Qp1. However, when the (110) silicon substrate 1 is used, the mobility of electrons in the n channel type MISFET Qn1 becomes lower as compared with the case where the (100) silicon substrate is used.

However, in Applied Example 4 of the present embodiment, in the silicon layer 1c of (100), the n channel type MISFET Qn1 was formed. Therefore, as described above, the mobility of electrons is increased, which can increase the on current. As a result, it is possible to improve the driving characteristics of the n channel type MISFET Qn1.

Thus, in the present embodiment, it is possible to improve the characteristics of both the p channel type MISFET Qp1 and the n channel type MISFET Qn1.

### Applied Example 5

In Applied Example 3, the dual stress liner structure was adopted. However, in a semiconductor device having a SRAM memory region, and peripheral circuit regions, in the peripheral circuit regions, the dual stress liner structure (see Applied Example 3) may be adopted, and in the SRAM memory region, a tensile stress film (tensile liner film) may be formed.

Specifically, in the semiconductor chip SM1 shown in FIG. 32, in the memory region 41 including a SRAM memory cell array formed therein, the tensile stress film is formed. The SRAM includes inverters coupled in a two-stage ring. The inverters forming the SRAM include those referred to as NMIS inverters and CMIS inverters. The NMIS denotes the n channel type MISFET, and the CMIS denotes the Complementary MISFET.

The NMIS inverter includes only an n channel type MISFET and high-resistance polysilicon. The CMIS inverter has an n channel type MISFET and a p channel type MISFET. The one using the NMIS inverters may be referred to as being in a 4Tr2R configuration, and the one using the CMIS inverters may be referred to as being in a 6Tr configuration.

In such a memory cell region 41 including SRAM memory cells in a 6Tr configuration formed therein, over the MISs of both the n channel type MISFET and the p channel type MISFET, the tensile stress film is formed. It is naturally understood that in the memory cell region 41 including the memory cells in the 4Tr2R configuration formed therein, the p channel type MISFET is not formed. Therefore, the tensile stress film may be formed.

Thus, in the memory region 41, also over the p channel type MISFET, the tensile stress film is formed. As a result, it is possible to increase the on current of the n channel type MISFET Qn1 forming the SRAM memory cell, and it is possible to reduce the standby leakage current of the SRAM memory cell.

On the other hand, in the peripheral circuit regions 42 of the semiconductor chip SM1 shown in FIG. 32, the dual stress liner structure described in details in Applied Example 3 is adopted.

Namely, the logic circuits formed in the peripheral circuit regions 42 have a plurality of n channel type MISFETs and p channel type MISFETs. In each peripheral circuit region 42, over the source/drain regions of the n channel type MISFET, the tensile stress film is formed, and over the source/drain regions of the p channel type MISFET, the compressive stress film 31 is formed (dual stress liner structure, see FIGS. 39 and 40 in Applied Example 3). Thus, in each peripheral circuit region 42, the dual stress liner structure is adopted. This can increase the mobility of electrons in the channel region of the n channel type MISFET. As a result, it is possible to increase the on current of the n channel type MISFET. Further, it is possible to increase the mobility of holes in the channel region of the p channel type MISFET, which can increase the on current of the p channel type MISFET.

Thus, in the peripheral circuit region 42, in order to increase the driving forces of both the MISFETs, the dual stress liner structure is adopted. In the memory region 41 including the SRAM memory cell array formed therein, in order to prevent the standby leakage of the memory cell, and the like, the tensile stress film may be formed over both the MISFETs.

Incidentally, the configurations and the manufacturing steps of Applied Examples 1 to 5 may be appropriately combined to be used. For example, the configurations of Applied Examples 1 to 5 described in the fifth embodiment may be each individually applied to the first to fourth embodiments. Alternatively, the configurations of Applied Examples 1 to 5 may be appropriately combined to be applied to the first to fourth embodiments.

Thus, the present invention is not limited to the embodiments, and various changes may be made within the scope not departing from the gist.

The present invention is effectively applicable to the semiconductor devices, and the manufacturing technologies thereof.

What is claimed is:

1. A semiconductor device, comprising:
(a) a substrate having a plane orientation of (110), and including a first semiconductor; and
(b) a p channel type field effect transistor formed in a first region of the substrate, having (b1) a gate electrode disposed over the first region via a gate insulation film, and (b2) source/drain regions disposed in the inside of a trench disposed in the substrate on the opposite sides of the gate electrode, and including a second semiconductor larger in lattice constant than the first semiconductor,
the trench having a first inclined surface with a plane orientation of (100), and a second inclined surface with a plane orientation of (100) crossing the first inclined surface, at a sidewall part situated on the gate electrode side.

2. The semiconductor device according to claim 1,
wherein the second semiconductor of the source/drain regions has a region epitaxially grown from the first inclined surface and the second inclined surface.

3. The semiconductor device according to claim 1,
wherein the first semiconductor is silicon (Si), and
wherein the second semiconductor is silicon germanium (SiGe).

4. The semiconductor device according to claim 1,
wherein the first semiconductor is silicon (Si),
wherein the second semiconductor is silicon germanium (SiGe), and
wherein the germanium concentration of the silicon germanium is 25 at % or more.

5. The semiconductor device according to claim 1,
wherein the first semiconductor is silicon (Si),
wherein the second semiconductor is silicon germanium (SiGe), and
wherein in the source/drain regions, the germanium concentration of the silicon germanium at the sidewall part of the trench is lower than the germanium concentrations of other regions.

6. The semiconductor device according to claim 1,
wherein the top surfaces of the source/drain regions including the second semiconductor are each formed at a position lower than the top surface of the gate insulation film.

7. The semiconductor device according to claim 1,
wherein over the source/drain regions including the second semiconductor, a compound layer of the first semiconductor and a metal is formed.

8. The semiconductor device according to claim 7,
wherein the first semiconductor is silicon, and
wherein the compound layer is a metal silicide layer.

9. The semiconductor device according to claim 6,
wherein over the source/drain regions, a compressive stress film is disposed.

10. The semiconductor device according to claim 1,
wherein the trench is formed by drying etching the substrate, and then, anisotropically wet etching the substrate.

11. The semiconductor device according to claim 1,
wherein a sidewall film is disposed on the opposite sides of the gate electrode, and
wherein the first inclined surface and the second inclined surface are situated under the sidewall film.

12. The semiconductor device according to claim 11,
wherein in the substrate on the opposite sides of the gate electrode, and under the sidewall film, a p type semiconductor region lower in concentration than the source/drain regions is disposed.

13. The semiconductor device according to claim 1, comprising an n channel type field effect transistor formed in a second region of the substrate, and having source/drain regions including the first semiconductor.

14. The semiconductor device according to claim 13,
wherein the n channel type field effect transistor has a second gate insulation film including a high dielectric constant insulation film disposed over the second region, and a second gate electrode including a metal or a metal compound disposed over the second gate insulation film.

15. The semiconductor device according to claim 1, comprising an n channel type field effect transistor having source/drain regions formed in a second region of the substrate, and including a third semiconductor smaller in lattice constant than the first semiconductor.

16. The semiconductor device according to claim 15,
wherein the first semiconductor is silicon (Si),
wherein the second semiconductor is silicon germanium (SiGe), and
wherein the third semiconductor is silicon carbide (SiC).

17. The semiconductor device according to claim 13,
wherein over the source/drain regions including the first semiconductor of the n channel type field effect transistor, a tensile stress film is disposed.

18. A semiconductor device, comprising:
(a) a substrate having a first region with a plane orientation of (110), and a second region with a plane orientation of (100), and including a first semiconductor;
(b) a p channel type field effect transistor formed in the first region of the substrate, having (b1) a first gate electrode disposed over the first region via a first gate insulation film, and (b2) first source/drain regions disposed in the inside of a trench disposed in the substrate on the opposite sides of the first gate electrode, and including a second semiconductor larger in lattice constant than the first semiconductor; and
(c) an n channel type field effect transistor formed in the second region of the substrate, having (c1) a second gate electrode disposed over the second region via a second gate insulation film, and (c2) second source/drain regions disposed in the substrate on the opposite sides of the second gate electrode, and including the first semiconductor,
the trench having a first inclined surface with a plane orientation of (100), and a second inclined surface with a plane orientation of (100) crossing the first inclined surface, at a sidewall part situated on the first gate electrode side.

19. A method for manufacturing a semiconductor device, comprising the steps of:
(a) preparing a substrate having at least a first region having a plane orientation of (110), and including a first semiconductor;
(b) forming a first gate electrode over the first region of the substrate via a first gate insulation film;
(c) forming a sidewall film on the opposite sides of the first gate electrode;
(d) with the sidewall film as a mask, dry etching the substrate on the opposite sides of the first gate electrode, and thereby forming a first trench in the substrate on the opposite sides of the first gate electrode;
(e) subjecting the first trench to anisotropic wet etching, and thereby forming a second trench having a first inclined surface with a plane orientation of (100), and a second inclined surface with a plane orientation of (100) crossing the first inclined surface at a sidewall part situated on the first gate electrode side; and
(f) epitaxially growing a second semiconductor larger in lattice constant than the first semiconductor from the first inclined surface and the second inclined surface, and thereby forming a semiconductor region including the second semiconductor in the second trench.

20. The method for manufacturing a semiconductor device according to claim 19,
wherein the first semiconductor is silicon (Si), and
wherein the anisotropic wet etching is performed using a solution containing tetramethylammonium hydroxide.

21. The method for manufacturing a semiconductor device according to claim 19,
wherein the step (e) is performed after a step of implanting ions into the bottom surface and the side surface of the first trench, to be performed after the step (d).

22. The method for manufacturing a semiconductor device according to claim 19,
wherein the substrate has a second region with a plane orientation of (100),
the method comprising a step of forming an n channel type field effect transistor in the second region.

23. The method for manufacturing a semiconductor device according to claim 22,
wherein the step of forming the n channel type MISFET has a step of forming a second gate electrode over the second region of the substrate via a second gate insulation film, and a step of forming source/drain regions including the first semiconductor on the opposite sides of the second gate electrode.

24. The method for manufacturing a semiconductor device according to claim 19,
wherein the first semiconductor is silicon (Si),
wherein the second semiconductor is silicon germanium (SiGe), and
wherein the epitaxial growth of the step (f) is performed with a silane series gas and a germane series gas as raw material gases, and is performed while increasing the ratio of the supply amount of the germane series gas to the supply amount of the silane series gas in the epitaxial growth.

25. The semiconductor device according to claim 1,
wherein the <110> direction which is a direction equivalent to the direction of the normal to a plane of which the plane orientation is (110) plane is the direction of a channel of the p channel type field effect transistor.
